(19) United States
(12) Patent Application Publication
(10) Pub. No.: US 2025/0318346 A1
(43) Pub. Date: Oct. 9, 2025

(54) DISPLAY DEVICE AND ELECTRIC APPARATUS

(71) Applicant: Samsung Display Co., Ltd., Yongin-Si, (KR)

(72) Inventors: DOGI LIM, Yongin-si (KR); SEUNGSOO BAEK, Yongin-si, (KR); WONHEE LEE, Yongin-si, (KR); KWANG-MIN LEE, Yongin-si, (KR); TAK YOUNG LEE, Yongin-si (KR)

(21) Appl. No.: 19/096,034

(22) Filed: Mar. 31, 2025

(30) Foreign Application Priority Data
Apr. 3, 2024 (KR) 10-2024-0045033

(51) Int. Cl. H10H 29/49

(52) U.S. Cl. CPC H10H 29/49

(57) ABSTRACT

A display device includes a substrate, a first partial power voltage line disposed on the substrate, and to which a power voltage is configured to be applied, a second partial power voltage line disposed in a same layer as the first partial power voltage line, spaced apart from the first partial power voltage line in a first direction, and to which the power voltage is configured to be applied, and a first connection pattern disposed on the first partial power voltage line, and which electrically connects the first partial power voltage line and the second partial power voltage line.

### CROSS-REFERENCE TO RELATED APPLICATION(S)

This application claims priority under 35 U.S.C. § 119 to Korean Patent Application No. 10-2024-0045033, filed on Apr. 3, 2024, which is hereby incorporated by reference for all purposes as if fully set forth herein.

### BACKGROUND

### 1. Field

Embodiments relate to a display device. More particularly, the embodiments relate to the display device that provides visual information.

### 2. Description of the Related Art

As information technology develops, importance of a display device, which are a

connecting medium between users and information, is increasing. For example, use of the display device, such as a liquid crystal display devices (LCD), an organic light-emitting display device (OLED), a plasma display device (PDP), and a quantum dot display device, is increasing.

The display device may include a display panel including a plurality of pixels and lower lines that apply voltage to the display panel. The voltage applied to the display panel include a first power voltage (ELVDD), a second power voltage (ELVSS), and the like. The pixels may emit light through the lower lines, and thus the display device may display images such as videos, characters, and the like.

### SUMMARY

Embodiments provide a display device with an improved durability.

A display device according to an embodiment may include a substrate, a first partial power voltage line disposed on the substrate, and to which a power voltage is configured to be applied, a second partial power voltage line disposed in a same layer as the first partial power voltage line, spaced apart from the first partial power voltage line in a first direction, and to which the power voltage is configured to be applied, and a first connection pattern disposed on the first partial power voltage line, and which electrically connects the first partial power voltage line and the second partial power voltage line.

In an embodiment, each of the first partial power voltage line and the second partial power voltage line may extend along a second direction which intersects with the first direction.

In an embodiment, the first connection pattern may overlap a portion of each of the first partial power voltage line and the second partial power voltage line, in a plan view.

In an embodiment, the display device may further include a second connection pattern disposed on the first connection pattern, and electrically connected with the first connection pattern.

In an embodiment, the second connection pattern may overlap a portion of each of the first partial power voltage line and the second partial power voltage line in a plan view.

In an embodiment, the display device may further include a gate insulating layer disposed between the first partial power voltage line and the second connection pattern and an interlayer insulating layer disposed between the first connection pattern and the second connection pattern.

In an embodiment, a first contact hole which extends to the first partial power voltage line and a second contact hole which extends to the second partial power voltage line may be defined in the gate insulating layer.

In an embodiment, the first connection pattern may contact the first partial power voltage line through the first contact hole, and may contact the second partial power voltage line through the second contact hole.

In an embodiment, in the interlayer insulating layer, a third contact hole extending to the second connection pattern may be defined, and the first connection pattern may contact the second connection pattern through the third contact hole.

In an embodiment, the display device may further include a third partial power voltage line spaced apart from the second partial power voltage line in the first direction, extending in a second direction which intersects with the first direction, and to which the power voltage is configured to be applied.

In an embodiment, a third contact hole extending to the third partial power voltage line may be defined in the gate insulating layer and the interlayer insulating layer, and the first connection pattern contacts the third partial power voltage line through the third contact hole.

In an embodiment, the first connection pattern and the second connection pattern may contact a portion of each of the first partial power voltage line, the second partial power voltage line, and the third partial power voltage line, in a plan view.

In an embodiment, the display device may further include a third partial power voltage line spaced apart from the first partial power voltage line in a second direction which intersects the first direction, and to which the power voltage is configured to be applied, and a fourth partial power voltage line spaced apart from the second partial power voltage line in the second direction, space apart from the third partial power voltage line in the first direction, and to which the power voltage is configured to be applied.

In an embodiment, a third contact hole which extends to the third partial power voltage line and a fourth contact hole which extends to the fourth partial power voltage line may be defined in the gate insulating layer and the interlayer insulating layer, and the first connection pattern may contact the third partial power voltage line and fourth partial power voltage line through the third contact hole and the fourth contact hole, respectively.

In an embodiment, the first connection pattern and the second connection pattern may overlap a portion of each of the first partial power voltage line, the second partial power voltage line, third partial power voltage line, and fourth partial power voltage line, in a plan view.

In an embodiment, the display device may further include a transistor including an active layer disposed on the first partial power voltage line, a gate electrode disposed on the active layer and a source electrode and a drain electrode contacting the active layer. The first connection pattern may be disposed in a same layer as the source electrode and the drain electrode, and the second connection pattern may be disposed in a same layer as the gate electrode.

A display device according to an embodiment may include a substate, a first power voltage line disposed on the substrate, and to which a first power voltage is configured to applied, a second power voltage line disposed in a same layer as the first partial power voltage line, a second partial power voltage line spaced apart from the first partial power voltage line, and to which the second power voltage is configured to be applied, and a connection pattern disposed on the first power voltage line, and electrically connecting the first partial power voltage line and the second partial power voltage line. The second power voltage line may include a first partial power voltage line spaced apart from the first power voltage line in a first direction, and to which a second power voltage, having a different level from the first power voltage, is configured to be applied, and a second partial power voltage line spaced apart from the first partial power voltage line, and to which the second power voltage is configured to be applied.

In an embodiment, the first partial power voltage line and the second partial power voltage line may be spaced apart from each other, and extend in a second direction which intersects with the first direction.

In an embodiment, the first partial power voltage line and the second partial power voltage line may be spaced apart in a second direction which intersects with the first direction.

In an embodiment, the display device may further include a third partial power voltage line spaced apart from the second partial power voltage line in the second direction, and to which the second power voltage is configured to be applied. The connection pattern electrically may connect the first partial power voltage line, the second partial power voltage line, and the third partial power voltage line.

In a display device according to embodiments of the present disclosure, the display device may include a first lower line to which a power voltage is applied, a second lower line disposed on a same layer as the first lower line, and to which the power voltage is applied, and a first connection pattern overlapping the first lower line and the second lower line. The first connection pattern may electrically connect the first lower line and the second lower line to each other. Accordingly, an electrical resistance of entire first lower line and the second lower line to which the power voltage is applied may be reduced, and a heat generation phenomenon generated in the first lower line and the second lower line may be reduced. Accordingly, a lifting phenomenon, which is generated when a portion of an active layer overlapping the second lower line and disposed on the second lower line is lost due to the heat generation phenomenon in conductive layers disposed on the active layer, may be reduced.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a circuit diagram illustrating a first sub-pixel included in the display device of FIG. 1.

FIGS. 3, 4, 5, 6, and 7 are plan views illustrating an example of a pixel included in the display device of FIG. 1.

FIG. 8 is a cross-sectional view illustrating a cross-section taken along a line I-I′ of FIG. 1.

FIG. 9 is a plan view illustrating a third-first lower line, a third-second lower line, a first active pattern, a second active pattern, a third active pattern, a second double pattern, a third double pattern, a fourth double pattern, a first upper electrode, a second upper electrode, and a third upper electrode included in the display device of FIG. 1.

FIG. 10 is a cross-sectional view illustrating a cross-section taken along a line II-II′ of FIG. 9.

FIG. 11 is a plan view illustrating another example of a pixel included in the display device of FIG. 1.

FIG. 12 is a plan view illustrating a third-first lower line, a third-second lower line, a third-third lower line, a second double pattern, a third double pattern, a fourth double pattern, a first upper electrode, a second upper electrode, and a third upper electrode included in the display device of FIG. 1.

FIG. 13 is a plan view illustrating still another example of a pixel included in the display device of FIG. 1.

FIG. 14 is a plan view illustrating a third-first lower line, a third-second lower line, a second double pattern, a third double pattern, a fourth double pattern, a first upper electrode, a second upper electrode, and a third upper electrode included in the display device of FIG. 1.

FIG. 15 is a plan view illustrating still another example of a pixel included in the display device of FIG. 1.

FIG. 16 is a plan view illustrating a third-first lower line, a third-second lower line, a third-third lower line, a third-fourth lower line, a second double pattern, a third double pattern, a fourth double pattern, a first upper electrode, a second upper electrode, and a third upper electrode included in the display device of FIG. 1.

FIG. 17 is a plan view illustrating still another example of a pixel included in the display device of FIG. 1.

FIG. 18 is a plan view illustrating a first-first lower line, a first-second lower line, a first double pattern, and a first line contact electrode included in the display device of FIG. 1.

FIG. 19 is a plan view illustrating still another example of a pixel included in the display device of FIG. 1.

FIG. 20 is a plan view illustrating a first-first lower line, a first-second lower line, a first-third lower line, a first double pattern, and a first line contact electrode included in the display device of FIG. 1.

### DETAILED DESCRIPTION OF THE EMBODIMENTS

Hereinafter, display devices in accordance with embodiments will be described in more detail with reference to the accompanying drawings. The same reference numerals are used for the same components in the drawings, and redundant descriptions of the same components will be omitted.

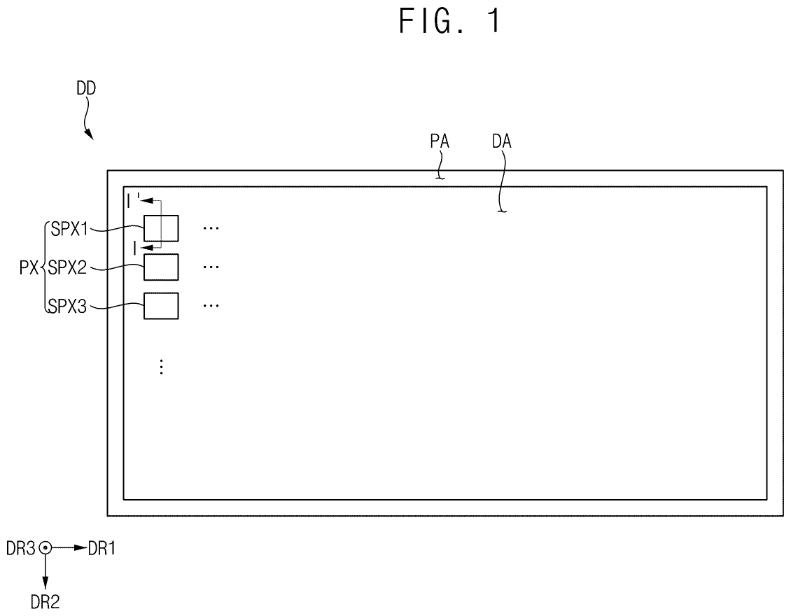

FIG. 1 is a plan view illustrating a display device DD according to an embodiment of the present disclosure.

Referring to FIG. 1, the display device DD according to an embodiment of the present disclosure may include a display area DA and a peripheral area PA. The display area DA may be defined as an area that generates an image, and the peripheral area PA may be defined as an area that does not generate an image.

At least one pixel PX may be arranged in the display area DA. The pixel PX may include a first sub-pixel SPX1, a second sub-pixel SPX2, and a third sub-pixel SPX3. For example, the first sub-pixel SPX1 may emit a first light, the second sub-pixel SPX2 may emit a second light, and the third sub-pixel SPX3 may emit a third light. In an embodiment, the first light may be red light, the second light may be green light, and the third light may be blue light. However, the present disclosure may not be limited thereto. For example, a plurality of pixels PX may be combined to emit yellow, cyan, and magenta lights.

In this specification, a plane may be defined by a first direction DR1 and a second direction DR2. For example, the second direction DR2 may be perpendicular to the first direction DR1. In addition, a third direction DR3, sometimes called a thickness direction DR3, may be perpendicular to the plane.

The first, second, and third sub-pixels SPX1, SPX2, and SPX3 may be repeatedly arranged along the first direction DR1 and the second direction DR2 which intersects the first direction DR1 in the plan view. For example, the second sub-pixel SPX2 may be adjacent to the first sub-pixel SPX1 in the second direction DR2. In addition, the third sub-pixel SPX3 may be adjacent to the second sub-pixel SPX2 in the second direction DR2.

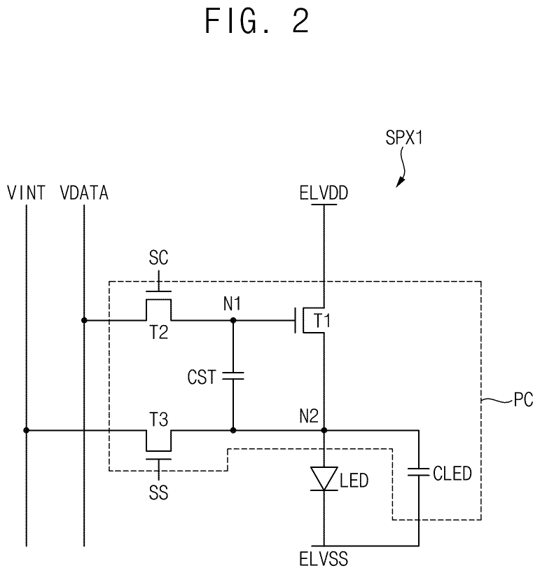

The peripheral area PA may be disposed around the display area DA. For example, the peripheral area PA may surround at least a portion of the display area DA. A driver may be disposed in the peripheral area PA. The driver may provide a signal or voltage to the pixel PX. For example, the driver may include a data driver, a gate driver, and the like. In addition, the voltage provided by the driver may include driving voltages (e.g., a first power voltage ELVDD and a second power voltage ELVSS of FIG. 2).

FIG. 2 is a circuit diagram illustrating the first sub-pixel SPX1 included in the display device DD of FIG. 1.

Referring to FIG. 2, the first sub-pixel SPX1 may include a pixel circuit PC and a light-emitting element LED electrically connected to the pixel circuit PC. The pixel circuit PC may include a first transistor T1, a second transistor T2, a third transistors T3, a storage capacitor CST, and a light-emitting capacitor CLED.

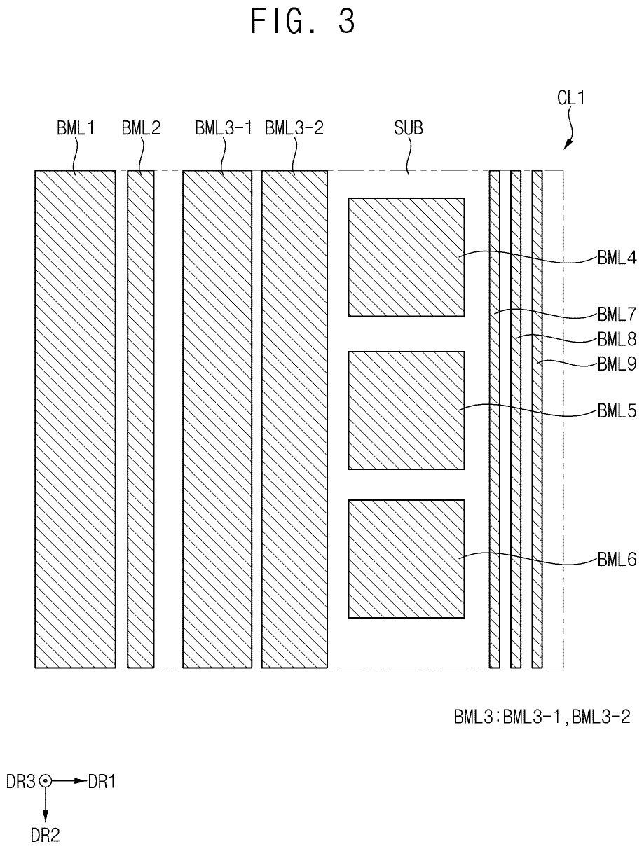

The first transistor T1 may include a first terminal, a gate terminal, and a second terminal. The gate terminal of the first transistor T1 may be connected to a first node N1. A first power voltage ELVDD may be applied to the first terminal of the first transistor T1. The second terminal of the first transistor T1 may be connected to a second node N2. The first transistor T1 may receive the first power voltage ELVDD from a lower line (e.g., a third lower line BML3 of FIG. 3) in response to the voltage of the first node N1 and supply a driving current to the light-emitting element LED. For example, the first transistor T1 may be a driving transistor for driving the light-emitting element LED.

The second transistor T2 may include a first terminal, a gate terminal, and a second terminal. A first scan signal SC may be applied to the gate terminal of the second transistor T2. A data voltage VDATA may be applied to the first terminal of the second transistor T2. The second terminal of the second transistor T2 may be connected to the first node N1. The second transistor T2 may be turned on by the first scan signal SC to electrically connect the lower line (e.g., a fifth lower line BML8 of FIG. 3) that provides the data voltage VDATA to the first node N1. For example, the second transistor T2 may be a switching transistor.

The third transistor T3 may include a first terminal, a gate terminal, and a second terminal. A second scan signal SS may be applied to the gate terminal of the third transistor T3. A initialization voltage VINT may be applied to the first terminal of the third transistor T3. The second terminal of the third transistor T3 may be connected to the second node N2. The third transistor T3 may be turned on by the second scan signal SS to electrically connect the initialization voltage line that provides the initialization voltage VINT to the second node N2. For example, the third transistor T3 may be an initialization transistor.

The storage capacitor CST may include a first terminal and a second terminal. The first terminal of the storage capacitor CST may be connected to a first node N1. The second terminal of the storage capacitor CST may be connected to a second node N2. The storage capacitor CST may store a differential voltage between a gate voltage and a source voltage of the first transistor T1.

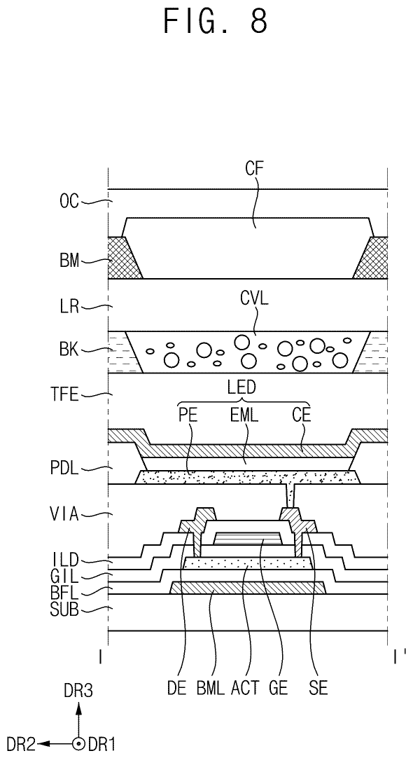

The light-emitting element LED may include a first electrode (e.g., a pixel electrode PE of FIG. 8) and a second electrode (e.g., a common electrode CE of FIG. 8). The first electrode of the light-emitting element LED may be connected to the second node N2. A second power voltage ELVSS may be applied to the second electrode of the light-emitting element LED. The light-emitting element LED may emit light with a brightness corresponding to a driving current provided from the pixel circuit PC.

The light-emitting capacitor CLED may include a first terminal and a second terminal. The first terminal of the light-emitting capacitor CLED may be connected to the second node N2. The second terminal of the light-emitting capacitor CLED may be connected to the second electrode of the light-emitting element LED. The light-emitting capacitor CLED may allow voltage applied to both ends of the light-emitting element LED to be maintained constant, thereby allowing the light-emitting element LED to display constant brightness.

However, in FIG. 2, one sub-pixel SPX1 is illustrated as including three transistors (e.g. the first, second, and third transistors T1, T2, T3), one storage capacitor CST, and one light-emitting capacitor CLED, but the embodiments of the present disclosure may not be limited thereto.

In addition, in FIG. 2, one first sub-pixel SPX1 is illustrated as including one light-emitting element LED, but the embodiments of the present disclosure may not be limited thereto. For example, one sub-pixel may include two or more light-emitting elements.

In addition, the second sub-pixel SPX2 of FIG. 1 may have substantially a same pixel circuit structure as the first sub-pixel SPX1. The third sub-pixel SPX3 of FIG. 1 may have substantially a same pixel circuit structure as the first sub-pixel SPX1.

FIGS. 3, 4, 5, 6, and 7 are plan views illustrating an example of a pixel included in the display device DD of FIG. 1.

FIG. 3 is a plan view for explaining a first conductive layer CL1.

Referring to FIG. 3, the display device DD may include a substrate SUB and a first conductive layer CL1. The substrate SUB may serve as a base of the display device DD. The first conductive layer CL1 may be disposed on the substrate SUB. The first conductive layer CL may include a first lower line BML1, a second lower line BML2, a third lower line BML3, a first lower electrode BML4, a second lower electrode BML5, a third lower electrode BML6, a fourth lower line BML7, a fifth lower line BML8, and a sixth lower line BML9.

The first conductive layer CL1 may include a metal, an alloy, a metal oxide, a transparent conductive material, and the like. Examples of materials used as the first conductive layer CL1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and the like. These may be used alone or in combination with each other. In addition, the first conductive layer CL1 may be composed of a single layer or multiple layers.

The second power voltage (e.g., the second power voltage ELVSS of FIG. 2) may be applied to the first lower line BML1. The second power voltage may have a second level. The second power voltage may flow in the second direction DR2 along the first lower line BML1. The second power voltage may be applied to light-emitting elements (e.g., the light-emitting element LED of FIG. 8) later.

The initialization voltage (e.g., the initialization voltage VINT of FIG. 2) may be applied to the second lower line BML2. The initialization voltage may flow in the second direction DR2 along the second lower line BML2. The second lower line BML2 may be spaced apart from the first lower line BML1 in the first direction DR1.

The first power voltage (e.g., the first power voltage ELVDD of FIG. 2) may be applied to the third lower line BML3. The first power voltage may flow in the second direction DR2 along the third lower line BML3. The first power voltage may have a first level different from the second level. For example, the first level may be greater than the second level.

The third lower line BML3 may include a third-first lower line BML3-1 and a third-second lower line BML3-2. The third-first lower line BML3-1 and the third-second lower line BML3-2 may be spaced apart from each other in a first direction DR1. In addition, each of the third-first lower line BML3-1 and the third-second lower line BML3-2 may extend in a second direction DR2. The first power voltage may be applied to the third-first lower line BML3-1 and the third-second lower line BML3-2. The third-first lower line BML3-1 and the third-second lower line BML3-2 may be electrically connected to each other. Accordingly, the third-first lower line BML3-1 and the third-second lower line BML3-2 may transmit the first power voltage to at least one pixel (e.g., the pixel PX of FIG. 1). In this specification, the third-first lower line BML3-1 and the third-second lower line BML3-2 may be referred to as a first partial power voltage line and a second partial power voltage line, respectively.

In addition, in this specification, the third lower line BML3 may be referred to as a first power voltage line or a second power voltage line. In addition, in this specification, the first lower line BML1 may also be referred to as a first power voltage line or a second power voltage line.

The first lower electrode BML4 may be spaced apart from the third-second lower line BML3-2 in the first direction DR1. In an embodiment, the first lower electrode BML4 may be electrically connected to the second lower line BML2 to which the initialization voltage is applied. For example, the first lower electrode BML4 may correspond to the second terminal of the storage capacitor (e.g., the storage capacitor CST of FIG. 2) included in the first sub-pixel (e.g., the first sub-pixel SPX1 of FIG. 1).

The second lower electrode BML5 may be spaced apart from the third-second lower line BML3-2 in the first direction DR1. In addition, the second lower electrode BML5 may be spaced apart from the first lower electrode BML4 in the second direction DR2. The second lower electrode BML5 may correspond to the second terminal of the storage capacitor included in the second sub-pixel (e.g., the second sub-pixel SPX2 of FIG. 1).

The third lower electrode BML6 may be spaced apart from the third-second lower line BML3-2 in the first direction DR1. In addition, the third lower electrode BML6 may be spaced apart from the second lower electrode BML5 in the second direction DR2. The third lower electrode BML6 may correspond to the second terminal of the storage capacitor included in the third sub-pixel (e.g., the third sub-pixel SPX3 of FIG. 1).

The first lower electrode BML4, the second lower electrode BML5, and the third lower electrode BML6 may have substantially a same planar profile (shape) as each other. However, in the present disclosure, the profile (shape) of the first lower electrode BML4, the second lower electrode BML5, and the third lower electrode BML6 may not be limited thereto.

The fourth lower line BML7 may be spaced apart from the first, second, and third lower electrodes BML4, BML5, and BML6 in the first direction DR1. In addition, the fourth lower line BML7 may extend in the second direction DR2. The fourth lower line BML7 may provide the data voltage (e.g., the data voltage DATA of FIG. 2) to the second sub-pixel.

The fifth lower line BML8 may be spaced apart from the fourth lower line BML7 in the first direction DR1. In addition, the fifth lower line BML8 may extend in the second direction DR2. The fifth lower line BML8 may provide the data voltage to the first sub-pixel.

The sixth lower line BML9 may be spaced apart from the fifth lower line BML8 in the first direction DR1. In addition, the sixth lower line BML9 may be extended in the second direction DR2. The sixth lower line BML9 may provide the data voltage to the third sub-pixel.

However, a connection relationship between the fourth, fifth, and sixth lower lines BML7, BML8, and BML9 and the first, second and third sub-pixels (e.g. the first, second and third sub-pixels SPX1, SPX2, and SPX3) may not be limited thereto. The connection relationship between the fourth, fifth, and sixth lower lines BML7, BML8, and BML9 and the first, second and third sub-pixels may be appropriately set as needed.

Referring further to FIGS. 1 and 3, the first, second, and third lower lines BML1, BML2, and BML3, the first, second, and third lower electrodes BML4, BML5, and BML6, and the fourth, fifth, and sixth lower lines BML7, BML8, and BML9 adjacent to each other may be included in one pixel PX. A plurality of pixels PX may be arranged in a plurality of iterations in the first direction DR1 and the second direction DR2. For example, the first lower line BML1 included in a pixel PX adjacent to the one pixel PX in the first direction DR1 may be disposed to be spaced apart from the sixth lower line BML9 included in the one pixel PX in the first direction DR1.

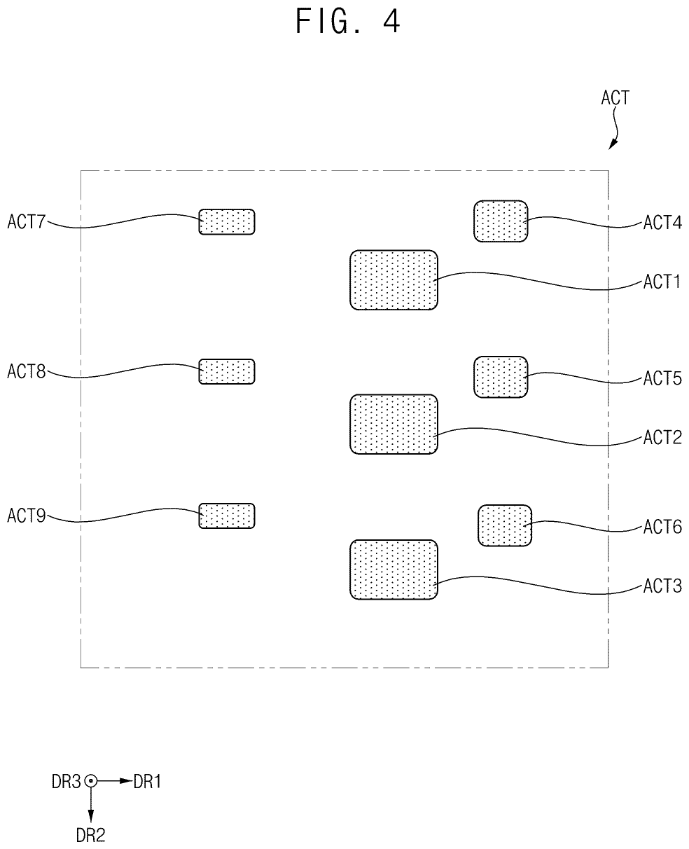

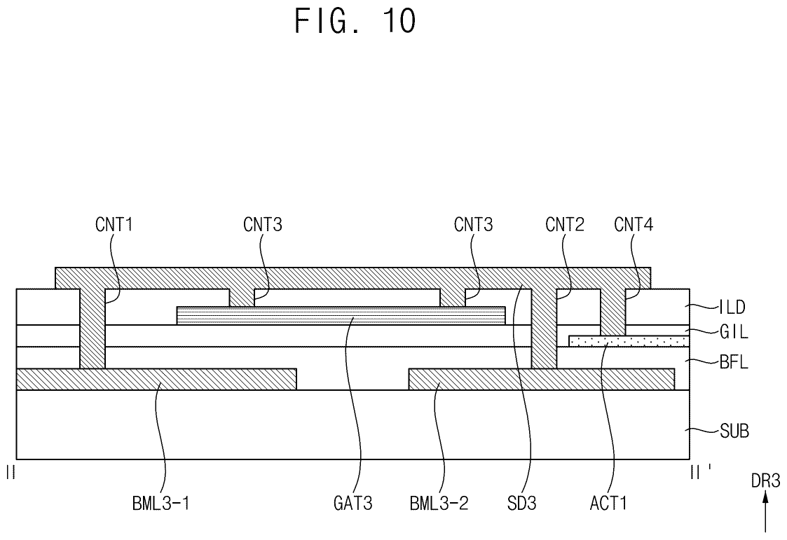

FIG. 4 is a plan view for explaining an active layer ACT disposed on the first conductive layer CL1. Specifically, a buffer layer BFL of FIG. 10 may be disposed on the first conductive layer CL1, and the active layer ACT may be disposed on the buffer layer BFL.

Referring to FIGS. 3 and 4, the active layer ACT may include a first active pattern ACT1, a second active pattern ACT2, a third active pattern ACT3, a fourth active pattern ACT4, a fifth active pattern ACT5, a sixth active pattern ACT6, a seventh active pattern ACT7, an eighth active pattern ACT8, and a ninth active pattern ACT9. The first, second, third, fourth, fifth, sixth, seventh, eighth, and ninth active patterns ACT1, ACT2, ACT3, ACT4, ACT5, ACT6, ACT7, ACT8, and ACT9 may be spaced apart from each other. In an embodiment, the active layer ACT may be formed of a silicon semiconductor material or an oxide semiconductor material. Examples of the silicon semiconductor material that may be used as the active layer ACT may include an amorphous silicon, a polycrystalline silicon, and the like. Examples of the oxide semiconductor material that may be used as the active layer ACT may include IGZO (InGaZnO), ITZO (InSnZnO), and the like. These may be used alone or in combination with each other.

The first, second, and third active patterns ACT1, ACT2, and ACT3 may be arranged along the second direction DR2. The first, second, and third active patterns ACT1, ACT2, and ACT3 may overlap the first, second, and third lower electrodes BML4, BML5, and BML6, respectively. In addition, at least a portion of each of the first, second, and third active patterns ACT1, ACT2, and ACT3 may overlap the third-second lower line BML3-2.

The first active pattern ACT1 may be electrically connected to the third lower line BML3 and may transmit the first power voltage to the first sub-pixel. For example, the first active pattern ACT1 may correspond to the first terminal and the second terminal of the first transistor (e.g., the first transistor T1 of FIG. 2) included in the first sub-pixel.

The second active pattern ACT2 may be electrically connected to the third lower line BML3 and may transmit the first power voltage to the second sub-pixel. For example, the second active pattern ACT2 may transmit the first power voltage to the second sub-pixel.

The third active pattern ACT3 may be electrically connected to the third lower line BML3 and may transmit the first power voltage to the third sub-pixel. For example, the third active pattern ACT3 may transmit the first power voltage to the third sub-pixel.

The fourth, fifth, and sixth active patterns ACT4, ACT5, and ACT6 may be spaced apart from each other in the second direction DR2. In addition, the fourth, fifth, and sixth active patterns ACT4, ACT5, and ACT6 may be arranged along the second direction DR2.

The fourth active pattern ACT4 may be electrically connected to the fifth lower line BML8 and may transmit the data voltage to the first sub-pixel. For example, the fourth active pattern ACT4 may correspond to the first terminal and the second terminal of the second transistor (e.g., the second transistor T2 of FIG. 2) included in the first sub-pixel.

The fifth active pattern ACT5 may be electrically connected to the fourth lower line BML7 and may transmit the data voltage to the second sub-pixel. The sixth active pattern ACT6 may be electrically connected to the sixth lower line BML9 and may transmit the data voltage to the third sub-pixel.

The seventh, eighth, and ninth active patterns ACT7, ACT8, and ACT9 may be spaced apart from each other in the second direction DR2. In addition, the seventh, eighth, and ninth active patterns ACT7, ACT8, and ACT9 may be arranged along the second direction DR2.

The seventh active pattern ACT7 may be electrically connected to the second lower line BML2 and may transmit an initialization voltage to the first sub-pixel. For example, the seventh active pattern ACT7 may correspond to the first terminal and the second terminal of the third transistor (e.g., the third transistor T3 of FIG. 2) included in the first sub-pixel.

In addition, the eighth active pattern ACT8 may be electrically connected to the second lower line BML2 and may transmit the initialization voltage to the second sub-pixel. The ninth active pattern ACT9 may be electrically connected to the second lower line BML2 and may transmit the initialization voltage to the third sub-pixel.

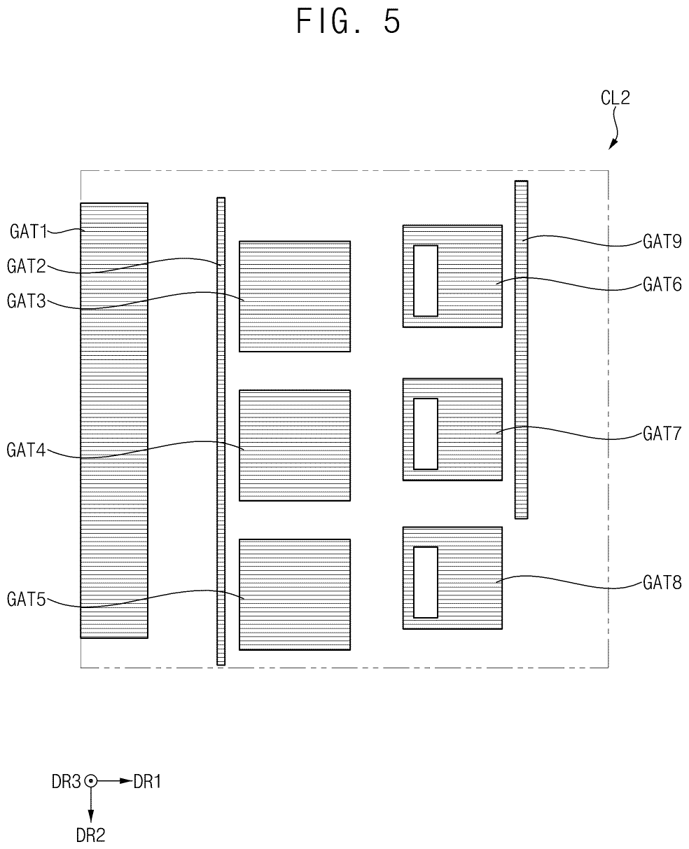

FIG. 5 is a plan view for explaining a second conductive layer CL2 disposed on the active layer ACT. Specifically, a gate insulating layer GIL of FIG. 8 may be disposed on the active layer ACT, and the second conductive layer CL2 may be disposed on the gate insulating layer GIL.

Referring to FIGS. 3, 4, and 5, the second conductive layer CL2 may include first double pattern GAT1, a first gate line GAT2, a second double pattern GAT3, a third double pattern GAT4, a fourth double pattern GAT5, a first gate electrode GAT6, a second gate electrode GAT7, a third gate electrode GAT8, and a second gate line GAT9.

The second conductive layer CL2 may include a metal, an alloy, a conductive metal oxide, a transparent conductive material, and the like. For example, the second conductive layer CL2 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and the like. These may be used alone or in combination with each other. In addition, the second conductive layer CL2 may be composed of a single layer or multiple layers.

The first double pattern GAT1 may overlap the first lower line BML1 to which the second power voltage is applied in a plan view. The first double pattern GAT1 may be electrically connected to the first lower line BML1. The first double pattern GAT1 may reduce the electrical resistance of the first lower line BML1. In addition, the first double pattern GAT1 may extend in the second direction DR2.

The first gate line GAT2 may extend in the second direction DR2 and may be spaced apart from the first double pattern GAT1 in the first direction DR1. The first gate line GAT2 may overlap the seventh, eighth, and ninth active patterns ACT7, ACT8, and ACT9 in a plan view. The first gate line GAT2 may provide the second scan signal (e.g., the second scan signal SS of FIG. 2) to the first, second, and third sub-pixels. The first gate line GAT2 may correspond to a gate terminal of each of the third transistors included in the first, second, and third sub-pixels.

The second double pattern GAT3, the third double pattern GAT4, and the fourth double pattern GAT5 may be arranged along the second direction DR2. The second double pattern GAT3, the third double pattern GAT4, and the fourth double pattern GAT5 may overlap the third lower line BML3. For example, the second double pattern GAT3 may overlap the third-first lower line BML3-1 and the third-second lower line BML3-2 in a plan view. The third double pattern GAT4 may overlap the third-first lower line BML3-1 and the third-second lower line BML3-2 in a plan view. The fourth double pattern GAT5 may overlap the third-first lower line BML3-1 and the third-second lower line BML3-2 in a plan view.

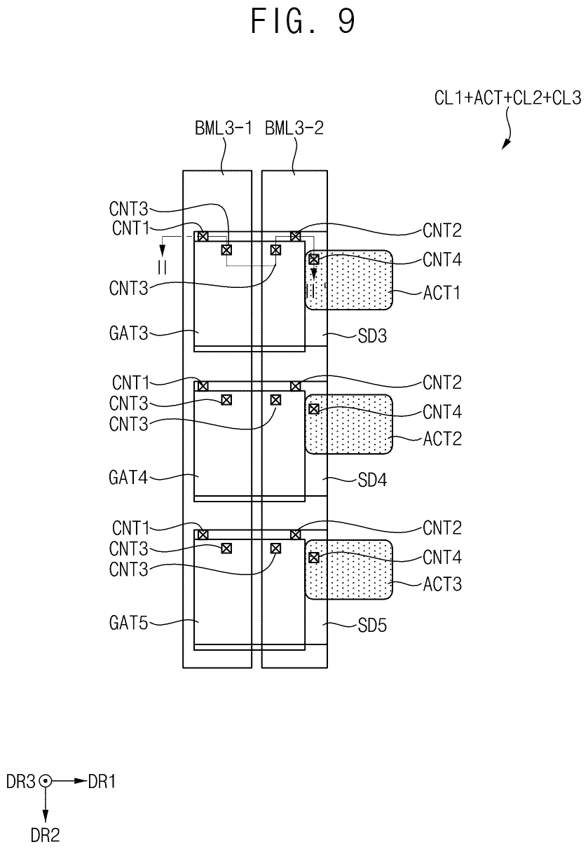

The third-first lower line BML3-1 and the third-second lower line BML3-2 may be electrically connected to each other through the second double pattern GAT3, the third double pattern GAT4, and the fourth double pattern GAT5, and an electrical resistance of the entire third lower line BML3 may be reduced. Accordingly, a voltage drop of the first power voltage may be prevented. This will be described later with reference to FIG. 9.

The first gate electrode GAT6, the second gate electrode GAT7, and the third gate electrode GAT8 may be spaced apart from each other in the second direction DR2. In addition, the first gate electrode GAT6, the second gate electrode GAT7, and the third gate electrode GAT8 may be arranged in the second direction DR2.

The first gate electrode GAT6 may overlap the first active pattern ACT1. Accordingly, the first gate electrode GAT6 may correspond to the gate terminal of the first transistor included in the first sub-pixel. The first gate electrode GAT6 may be electrically connected to the fourth active pattern ACT4. Accordingly, the second terminal of the second transistor included in the first sub-pixel may be electrically connected to the gate terminal of the first transistor. The first gate electrode GAT6 may correspond to the first terminal of the storage capacitor included in the first sub-pixel.

The second gate electrode GAT7 may overlap the second active pattern ACT2 and be electrically connected to the fifth active pattern ACT5. The second gate electrode GAT7 may correspond to the first terminal of the storage capacitor included in the second sub-pixel.

The third gate electrode GAT8 may overlap the third active pattern ACT3 in a plan view and be electrically connected to the sixth active pattern ACT6. The third gate electrode GAT8 may correspond to a first terminal of a storage capacitor included in the third sub-pixel.

The second gate line GAT9 may extend in the second direction DR2 and may be spaced apart from the first and second gate electrodes GAT6 and GAT7 in the first direction DR1. The second gate line GAT9 may overlap the fourth, fifth, and sixth active patterns ACT4, ACT5, and ACT6 in a plan view. The first gate line GAT2 may provide a first scan signal (e.g., the first scan signal SC of FIG. 2) to the first, second, and third sub-pixels. The second gate line GAT9 may correspond to a gate terminal of each of the second transistors included in the first, second, and third sub-pixels.

Referring further to FIGS. 1 and 5, the first double pattern GAT1, the first gate line GAT2, the second double pattern GAT3, the third double pattern GAT4, the fourth double pattern GAT5, the first gate electrode GAT6, the second gate electrode GAT7, the third gate electrode GAT8, and the second gate line GAT9, which are adjacent to each other, may be included in one pixel PX. A plurality of pixels PX may be repeatedly arranged in a plurality of directions in the first direction DR1 and the second direction DR2. For example, the first double pattern GAT1 included in a pixel PX adjacent to one pixel PX in the first direction DR1 may be arranged to be spaced apart from the second gate line GAT9 included in the one pixel PX in the first direction DR1.

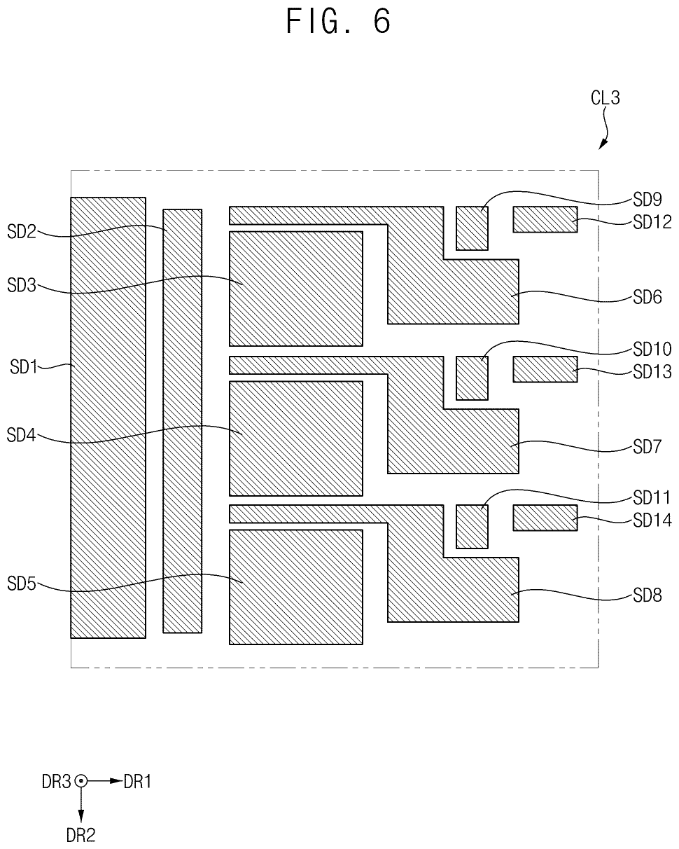

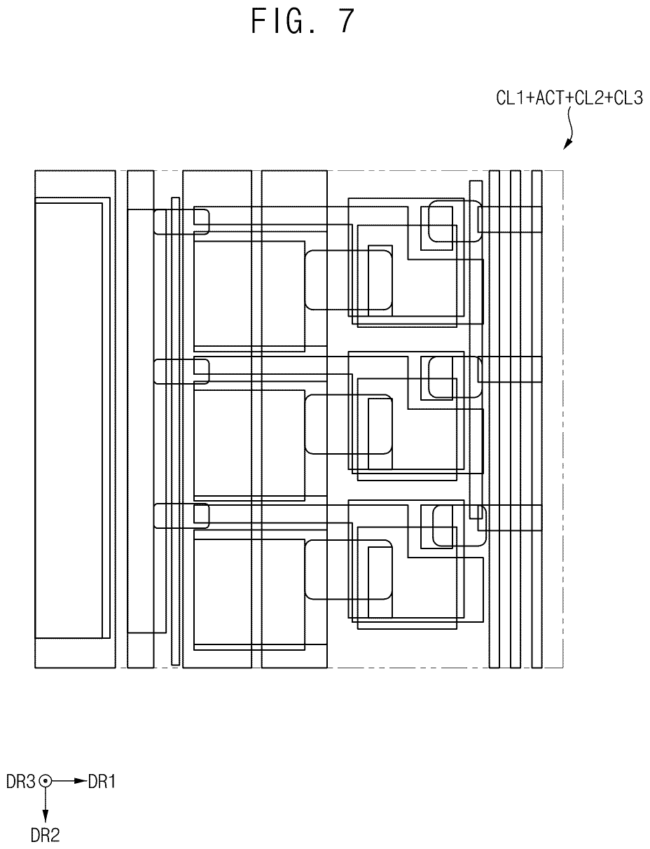

FIG. 6 is a plan view for explaining a third conductive layer CL3. Specifically, an interlayer insulating layer ILD of FIG. 8 may be disposed on the second conductive layer CL2, and the third conductive layer CL3 may be disposed on the interlayer insulating layer ILD. FIG. 7 is a plan view for explaining the state in which the first conductive layer CL1, the active layer ACT, the second conductive layer CL2, and the third conductive layer CL3 are stacked.

Referring to FIGS. 3, 4, 5, 6, and 7, the third conductive layer CL3 may include a first line contact electrode SD1, a second line contact electrode SD2, and a first upper electrode SD3, a second upper electrode SD4, a third upper electrode SD5, a fourth upper electrode SD6, a fifth upper electrode SD7, a sixth upper electrode SD8, a seventh upper electrode SD9, an eighth upper electrode SD10, a ninth upper electrode SD11, a tenth upper electrode SD12, an eleventh upper electrode SD13, and a twelfth upper electrode SD14. Components included in the third conductive layer CL3 may be electrically connected to components included in each of the first conductive layer CL1 and the second conductive layer CL2 through a contact hole. For example, the contact hole may penetrate at least one of the gate insulating layer GIL and the interlayer insulating layer ILD of FIG. 8 in the third direction DR3.

The third conductive layer CL3 may include a metal, an alloy, a conductive metal oxide, a transparent conductive material, and the like. For example, the third conductive layer CL3 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and the like. These may be used alone or in combination with each other. In addition, the third conductive layer CL3 may be composed of a single layer or multiple layers. The first line contact electrode SD1 may extend in the second direction DR2. The

first line contact electrode SD1 may overlap the first lower line BML1. The first line contact electrode SD1 may contact the first lower line BML1 through the contact hole. In addition, the first line contact electrode SD1 may contact the first double pattern GAT1 through the contact hole.

The second line contact electrode SD2 may overlap the second lower line BML2. The second line contact electrode SD2 may be spaced apart from the first line contact electrode SD1 in the first direction DR1. The second line contact electrode SD2 may contact the second lower line BML2 and the seventh, and eighth ninth active patterns ACT7, ACT8, and ACT9 through the contact hole. The second line contact electrode SD2 may transmit the initialization voltage from the second lower line BML2 to each of the seventh, eighth, and ninth active patterns ACT7, ACT8, and ACT9.

The first, second, and third upper electrodes SD3, SD4, and SD5 may be spaced apart from each other in a second direction DR2. In addition, the first, second, and third upper electrodes SD3, SD4, and SD5 may be arranged along the second direction DR2. Each of the first, second, and third upper electrodes SD3, SD4, and SD5 may be spaced apart from the second line contact electrode SD2 in the first direction DR1.

The first upper electrode SD3 may contact the third lower line BML3, the first active pattern ACT1, and the second double pattern GAT3 through the contact hole. Accordingly, the first upper electrode SD3 may transmit the first power voltage from the third lower line BML3 to the first active pattern ACT1. In addition, the first upper electrode SD3 may contact the third-first lower line BML3-1 and the third-second lower line BML3-2 through the contact hole. This will be described later with reference to FIG. 9.

The second upper electrode SD4 may contact the third lower line BML3, the second active pattern ACT2, and the third double pattern GAT4 through the contact hole. Accordingly, the second upper electrode SD4 may transmit the first power voltage from the third lower line BML3 to the second active pattern ACT2. In addition, the second upper electrode SD4 may contact the third-first lower line BML3-1 and the third-second lower line BML3-2 through the contact hole. This will be described later with reference to FIG. 9.

The third upper electrode SD5 may contact the third lower line BML3, the third active pattern ACT3, and the fourth double pattern GAT5 through the contact hole. Accordingly, the third upper electrode SD5 may transmit the first power voltage from the third lower line BML3 to the third active pattern ACT3. In addition, the third upper electrode SD5 may contact each of the third-first lower line BML3-1 and the third-second lower line BML3-2 through the contact hole. This will be described later with reference to FIG. 9.

The fourth, fifth, and sixth upper electrodes SD6, SD7, and SD may be spaced apart from each other in the second direction DR2. In addition, the fourth, fifth, and sixth upper electrodes SD6, SD7, and SD8 may be arranged along the second direction DR2. The fourth, fifth, and sixth upper electrodes SD6, SD7, and SD8 may be spaced apart from the first, second, and third upper electrodes SD3, SD4, and SD5, respectively.

The fourth upper electrode SD6 may contact the first lower electrode BML4, the seventh active pattern ACT7, and the first active pattern ACT1 through the contact hole. The fourth upper electrode SD6 may transmit the initialization voltage from the seventh active pattern ACT7 to the first lower electrode BML4.

The fifth upper electrode SD7 may contact the second lower electrode BML5, the eighth active pattern ACT8, and the second active pattern ACT2 through the contact hole. The fifth upper electrode SD7 may transmit the initialization voltage from the eighth active pattern ACT8 to the second lower electrode BML5.

The sixth upper electrode SD8 may contact the third lower electrode BML6, the ninth active pattern ACT9, and the third active pattern ACT3 through the contact hole. The sixth upper electrode SD8 may transfer the initialization voltage from the ninth active pattern ACT9 to the third lower electrode BML6.

The seventh, eighth, and ninth upper electrodes SD9, SD10, and SD11 may be spaced apart from each other in the second direction DR2. In addition, the seventh, eighth, and ninth upper electrodes SD9, SD10, and SD11 may be arranged along the second direction DR2. The seventh, eighth, and ninth upper electrodes SD9, SD10, and SD11 may be spaced apart from the fourth, fifth, and sixth upper electrodes SD6, SD7, and SD8, respectively.

The seventh upper electrode SD9 may overlap the fourth active pattern ACT4 and the first gate electrode GAT6 in a plan view. The seventh upper electrode SD9 may contact the fourth active pattern ACT4 and the first gate electrode GAT6 through the contact hole. Accordingly, the seventh upper electrode SD9 may transfer the data voltage from the fourth active pattern ACT4 to the first gate electrode GAT6.

The eighth upper electrode SD10 may overlap the fifth active pattern ACT5 and the second gate electrode GAT7 in a plan view. The eighth upper electrode SD10 may contact the fifth active pattern ACT5 and the second gate electrode GAT7 through the contact hole. Accordingly, the eighth upper electrode SD10 may transfer the data voltage from the fifth active pattern ACT5 to the second gate electrode GAT7.

The ninth upper electrode SD11 may overlap the sixth active pattern ACT6 and the third gate electrode GAT8 in a plan view. The ninth upper electrode SD11 may contact the sixth active pattern ACT6 and the third gate electrode GAT8 through the contact hole. Accordingly, the ninth upper electrode SD11 may transmit the data voltage from the sixth active pattern ACT6 to the third gate electrode GAT8.

The tenth, eleventh, and twelfth upper electrodes SD12, SD13, and SD14 may be spaced apart from each other in the second direction DR2. The tenth, eleventh, and twelfth upper electrodes SD12, SD13, and SD14 may be arranged along the second direction DR2. The tenth to twelfth upper electrodes SD12, SD13, and SD14 may be spaced apart from the seventh to ninth upper electrodes SD9, SD10, and SD11, respectively.

The tenth upper electrode SD12 may contact the fifth lower line BML8 and the fourth active pattern ACT4 through the contact hole. In other words, the tenth upper electrode SD12 may electrically connect the fifth lower line BML8 and the fourth active pattern ACT4. Accordingly, the tenth upper electrode SD12 may transmit the data voltage from the fifth lower line BML8 to the fourth active pattern ACT4.

The eleventh upper electrode SD13 may contact the fourth lower line BML7 and the fifth active pattern ACT5 through the contact hole. In other words, the eleventh upper electrode SD13 may electrically connect the fourth lower line BML7 and the fifth active pattern ACT5. Accordingly, the eleventh upper electrode SD13 may transmit the data voltage from the fourth lower line BML7 to the fifth active pattern ACT5.

The twelfth upper electrode SD14 may contact the sixth lower line BML9 and the sixth active pattern ACT6 through the contact hole. In other words, the twelfth upper electrode SD14 may electrically connect the sixth lower line BML9 and the sixth active pattern ACT6. Accordingly, the twelfth upper electrode SD14 may transmit the data voltage from the sixth lower line BML9 to the sixth active pattern ACT6.

Referring further to FIGS. 1 and 6, the first line contact electrode SD1, the second line contact electrode SD2, and the first, second, third, fourth, fifth, sixth, seventh, eighth, ninth, tenth, eleventh, and twelfth upper electrodes SD3, SD4, SD5, SD6, SD7, SD8, SD9, SD10, SD11, SD12, SD13, and SD14 that are adjacent to each other may be included in one pixel PX. A plurality of pixels PX may be repeatedly arranged in the first directions DR1 and in the second direction DR2. For example, the first line contact electrode SD1 included in a pixel PX that is adjacent to one pixel PX in the first direction DR1 may be arranged to be spaced apart from the tenth, eleventh, and twelfth upper electrodes SD12, SD13, and SD14 included in the one pixel PX in the first direction DR1.

However, components included in the third conductive layer CL3 of the present disclosure may not be limited thereto, and the third conductive layer CL3 may further include a plurality of lines extending along the first direction DR1. For example, a plurality of lines extending along the first direction DR1 may include a first line to which the second power voltage is applied, a second line to which the first scan signal is applied, and a third line to which the second scan signal is applied. The first line may be electrically connected to the first lower line BML1, and the first line, together with the first lower line BML1, may transmit the second power voltage to the first, second, and third sub-pixels SPX1, SPX2, and SPX3. In addition, the second line may be electrically connected to the second gate line GAT9, and the second line, together with the second gate line GAT9, may transmit the first scan signal to the first, second, and third sub-pixels SPX1, SPX2, and SPX3. The third line may be electrically connected to the first gate line GAT2, and the third line, together with the first gate line GAT2, may transmit the second scan signal to the first, second, and third sub-pixels SPX1, SPX2, and SPX3.

FIG. 8 is a cross-sectional view illustrating a cross-section taken along a line I-I′ of FIG. 1. For example, FIG. 8 is a cross-section of an area corresponding to the first sub-pixel SPX1 of FIG. 1. The second sub-pixel SPX2 and the third sub-pixel SPX3 may also include substantially a same structure as the first sub-pixel SPX1.

Referring to FIG. 8, the display device DD of FIG. 1 may include the substrate SUB, a lower metal layer BML, the buffer layer BFL, the active layer ACT, the gate insulating layer GIL, a gate electrode GE, the interlayer insulating layer ILD, a source electrode SE, a drain electrode DE, a via insulating layer VIA, a pixel electrode PE, a pixel defining layer PDL, an light-emitting layer EML, a common electrode CE, an encapsulation layer TFE, a bank layer BK, a color conversion layer CVL, a refractive layer LR, a light-blocking layer BM, a color filter CF, and a planarization layer OC.

The substrate SUB may include a transparent or opaque material. In an embodiment, examples of materials that may be used as the substrate SUB may include glass, quartz, plastic, and the like. These may be used alone or in combination.

The lower metal layer BML may be disposed on the substrate SUB. Specifically, the first conductive layer (e.g., the first conductive layer CL1 of FIG. 3) including the lower metal layer BML may be disposed on the substrate SUB. The lower metal layer BML may correspond to the first, second, and third lower electrodes BML4, BML5, and BML6 of FIG. 3.

The buffer layer BFL may be disposed on the lower metal layer BML. For example, the buffer layer BFL may cover the first conductive layer. The buffer layer BFL may prevent metal atoms or impurities from diffusing from the substrate SUB to the active layer (e.g., the active layer ACT of FIG. 4). In addition, the buffer layer BFL may control the rate of heat supply during the crystallization process for forming the active layer. The buffer layer BFL may include an insulating material. The insulating material may include silicon oxide, silicon nitride, silicon oxynitride, and the like. These may be used alone or in combination with each other.

The active layer ACT may be disposed on the buffer layer BFL. Specifically, the active layer ACT of FIG. 8 may correspond to the first, second, and third active patterns ACT1, ACT2, ACT3 of FIG. 4.

The gate insulating layer GIL may be disposed on the active layer ACT. The gate insulating layer GIL may cover the active layer ACT. The gate insulating layer GIL may include an insulating material. For example, the insulating material may include silicon oxide, silicon nitride, silicon oxynitride, and the like. These may be used alone or in combination with each other.

The gate electrode GE may be disposed on the gate insulating layer GIL. Specifically, a second conductive layer including a gate electrode GE (e.g., the second conductive layer CL2 of FIG. 5) may be disposed on a gate insulating layer GIL. The gate electrode GE may correspond to the first, second, and third gate electrodes GAT6, GAT7, and GAT8.

The interlayer insulating layer ILD may be disposed on the gate electrode GE. The interlayer insulating layer ILD may cover the second conductive layer. The interlayer insulating layer ILD may include an insulating material. For example, the insulating material may include silicon oxide, silicon nitride, silicon oxynitride, and the like. These may be used alone or in combination. In addition, the interlayer insulating layer ILD may be configured as a single layer or multiple layers.

The source electrode SE and the drain electrode DE may be disposed on the interlayer insulating layer ILD. Specifically, a third conductive layer (e.g., the third conductive layer CL3 of FIG. 6) including a source electrode SE and a drain electrode DE may be disposed on an interlayer insulating layer ILD. The source electrode SE may correspond to the fourth, fifth, and sixth upper electrodes SD6, SD7, SD8. In addition, the drain electrode DE may correspond to the first, second, and third upper electrodes SD3, SD4, and SD5. However, the present disclosure may not be limited thereto, and when the first transistor T1 of FIG. 2 is a PMOS transistor, the source electrode SE may correspond to the first, second, and third upper electrodes SD3, SD4, and SD5, and the drain electrode DE may correspond to the fourth, fifth, and sixth upper electrodes SD6, SD7, and SD8.

The via insulating layer VIA may be disposed on the source electrode SE and the drain electrode DE. The via insulating layer VIA may cover the third conductive layer. The via insulating layer VIA may include an insulating material. For example, the insulating material may include photoresist, polyacrylic resin, polyimide resin, acrylic resin, and the like. These may be used alone or in combination with each other.

The pixel electrode PE may be disposed on the via insulating layer VIA. The pixel electrode PE may contact the source electrode SE through a contact hole penetrating the via insulating layer VIA in the third direction DR3. The pixel electrode PE may be supplied with the initialization voltage or the driving current through the source electrode SE.

The pixel defining layer PDL may be disposed on the via insulating layer VIA. The pixel defining layer PDL may include an insulating material. For example, the insulating material may include photoresist, polyacrylic resin, polyimide resin, acrylic resin, and the like. These may be used alone or in combination with each other. The pixel defining layer PDL may define an opening that extends to and exposes at least a portion of the pixel electrode PE.

The light-emitting layer EML may be disposed on the pixel electrode PE. The light-emitting layer EML may include an organic material. The light-emitting layer EML may emit light of a specific color.

The common electrode CE may be disposed on the light-emitting layer EML. The common electrode CE may include a metal, an alloy, a conductive metal oxide, a conductive metal nitride, a transparent conductive material, and the like. For example, the common electrode CE may include aluminum (Al), platinum (Pt), silver (Ag), magnesium (Mg), gold (Au), chromium (Cr), tungsten (W), titanium (Ti), and the like. These may be used alone or in combination.

The pixel electrode PE, the light-emitting layer EML, and the common electrode CE may form a light-emitting element LED.

The encapsulation layer TFE may be disposed on the common electrode CE. The encapsulation layer TFE may be formed of an insulating material. For example, the encapsulation layer TFE may have a structure in which inorganic layers and organic layers are alternately laminated. The encapsulation layer TFE may prevent foreign substances from penetrating into the light-emitting element LED.

The bank layer BK may be disposed on the encapsulation layer TFE. The bank layer BK may be formed of a light-blocking material and may block light emitted from below. In addition, an opening exposing the encapsulation layer TFE may be formed in the bank layer BK.

The color conversion layer CVL may overlap the light-emitting layer EML. In an embodiment, the color conversion layer CVL may convert the wavelength of light emitted from the light-emitting layer EML. For example, the color conversion layer CVL may include a fluorescent substance, a scattering substance, a quantum dot, and the like. In an embodiment, as light emitted from the light emitting layer EML included in the first sub-pixel SPX1 of FIG. 1 passes through the color conversion layer CVL, the first light may be emitted. As light emitted from the light emitting layer EML included in the second sub-pixel SPX2 of FIG. 1 passes through the color conversion layer CVL, green light may be emitted. As light emitted from the light emitting layer EML included in the third sub-pixel SPX3 of FIG. 1 passes through the color conversion layer CVL, blue light may be emitted.

In an embodiment, the refractive layer LR may be disposed on the color conversion layer CVL. The refractive layer LR may have a predetermined refractive index different from adjacent layers. Accordingly, the light efficiency of the display device may be improved. In an embodiment, the refractive layer LR may be disposed under the color conversion layer CVL. In addition, in an embodiment, the refractive layer LR may include first and second refractive layers, the first refractive layer may be disposed on the color conversion layer CVL, and the second refractive layer may be disposed under the color conversion layer CVL.

The light-blocking layer BM may be disposed on the refractive layer LR. The light-blocking layer BM may be formed of a light-blocking material and may block light emitted from the bottom. In addition, an opening may be formed in the light-blocking layer BM that extends to and exposes the refractive layer LR.

The color filter CF may overlap the color conversion layer CVL. In an embodiment, the color filter CF corresponding to the first sub-pixel SPX1 of FIG. 1 may transmit light having a wavelength corresponding to red light. The color filter CF corresponding to the second sub-pixel SPX2 of FIG. 1 may transmit light having a wavelength corresponding to green light. The color filter CF corresponding to the third sub-pixel SPX3 of FIG. 1 may transmit light having a wavelength corresponding to blue light.

The planarization layer OC may be disposed on the color filter CF. The planarization layer OC may be formed of an organic material and may provide a substantially flat upper surface.

The structure of the display device described with reference to FIG. 8 may be variously changed according to embodiments, and may not be necessarily limited thereto.

FIG. 9 is a plan view illustrating a third-first lower line BML3-1, a third-second lower line BML3-2, a first active pattern ACT1, a second active pattern ACT2, a third active pattern ACT3, a second double pattern GAT3, a third double pattern GAT4, a fourth double pattern GAT5, a first upper electrode SD3, a second upper electrode SD4, and a third upper electrode SD5 included in the display device DD of FIG. 1. FIG. 10 is a cross-sectional view illustrating a cross-section taken along a line II-II′ of FIG. 9.

Hereinafter, contents that overlap contents described with reference to FIGS. 3, 4, 5, 6, 7, and 8 will be omitted or simplified.

Referring to FIGS. 3, 4, 5, 6, 7, 8, 9, and 10, the first, second, and third upper electrodes SD3, SD4, and SD5 may overlap a portion of each of the third-first lower line BML3-1 and the third-second lower line BML3-2. The second, third, and fourth double patterns GAT3, GAT4, and GAT5 may overlap a portion of each of the third-first lower line BML3-1 and the third-second lower line BML3-2.

A first contact hole CNT1 extending to and exposing the third-first lower line BML3-1 may be defined in the gate insulating layer GIL and the interlayer insulating layer ILD. The first contact hole CNT1 may penetrate the buffer layer BFL, the gate insulating layer GIL, and the interlayer insulating layer ILD in the thickness direction DR3. The first upper electrode SD3 may contact the third-first lower line BML3-1 through the first contact hole CNT1.

A second contact hole CNT2 extending to and exposing the third-second lower line BML3-2 may be defined in the gate insulating layer GIL and the interlayer insulating layer ILD. The second contact hole CNT2 may penetrate the buffer layer BFL, the gate insulating layer GIL, and the interlayer insulating layer ILD in the thickness direction DR3. The first upper electrode SD3 may contact the third-second lower line BML3-2 through the second contact hole CNT2.

The first upper electrode SD3 may electrically connect the third-first lower line BML3-1 and the third-second lower line BML3-2. The second upper electrode SD4 and the third upper electrode SD5 may also contact the third-first lower metal layer BML3-1 and the third-second lower line BML3-2 through the first and second contact holes CNT1, CNT2, respectively. In this specification, the first, second, and third upper electrodes SD3, SD4, and SD5 may be referred to as first connection patterns.

A third contact hole CNT3 extending to and exposing the second, third, and fourth double patterns GAT3, GAT4, and GAT5 may be defined in the interlayer insulating layer ILD. The third contact hole CNT3 may penetrate the interlayer insulating layer ILD in the thickness direction DR3. The first, second, and third upper electrodes SD3, SD4, and SD5 may contact the second, third, and fourth double patterns GAT3, GAT4, and GAT5, respectively, through the third contact hole CNT3. In this specification, the second, third, and fourth double patterns GAT3, GAT4, and GAT5 may be referred to as second connection patterns.

A fourth contact hole CNT4 extending to and exposing the first, second, and third active patterns ACT1, ACT2, and ACT3 may be defined in the gate insulating layer GIL and the interlayer insulating layer ILD. The fourth contact hole CNT4 may penetrate the gate insulating layer GIL and the interlayer insulating layer ILD in the thickness direction DR3. The first, second, and third upper electrodes SD3, SD4, and SD5 may contact the first, second, and third active patterns ACT1, ACT2, and ACT3, respectively, through the fourth contact hole CNT4.

However, the present disclosure may not be limited thereto, and the first, second, and third upper electrodes SD3, SD4, and SD5 may directly contact the third-first lower metal layer BML3-1 and the third-second lower metal layer BML3-2 through contact holes penetrating the gate insulating layer GIL and the buffer layer BFL.

The third-first lower line BML3-1 and the third-second lower line BML3-2 may be connected in parallel to each other through the second, third, and fourth double patterns GAT3, GAT4, and GAT5 and the first, second, and third upper electrodes SD3, SD4, and SD5. In an embodiment, an area of each of the third-first lower line BML3-1 and the third-second lower line BML3-2 may be about 0.22 cm² or less. Accordingly, an electrical resistance of the entire third-first lower line BML3-1 and the third-second lower line BML3-2 to which the first power voltage is applied may be reduced, and a heat generation phenomenon generated in the third-first lower line BML3-1 and the third-second lower line BML3-2 may be reduced. Accordingly, a lifting phenomenon, which is generated when a portion of each of the first, second, and third active patterns ACT1, ACT2, and ACT3 overlapping the third-second lower line BML3-2 is lost due to the heat generation phenomenon in the second and third conductive layers CL2 and CL3, may be reduced.

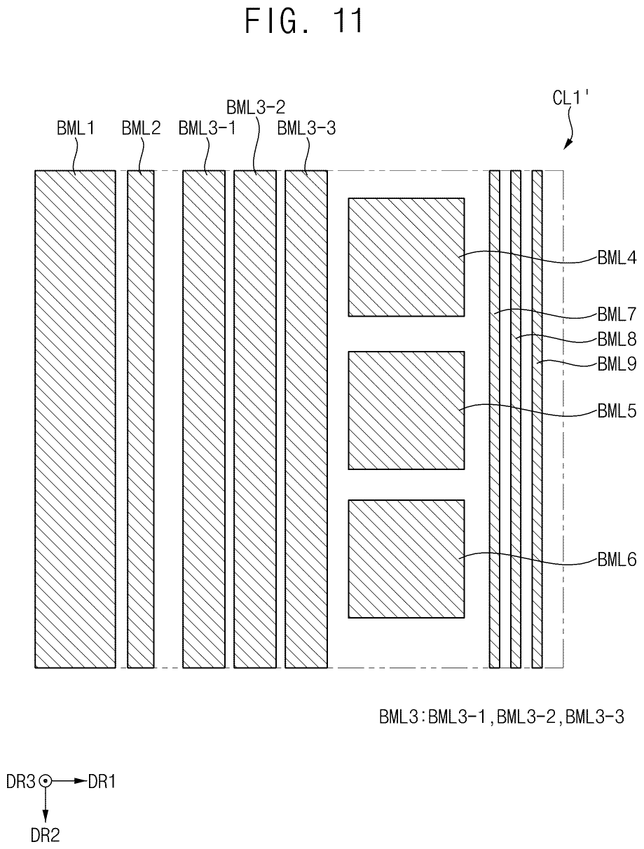

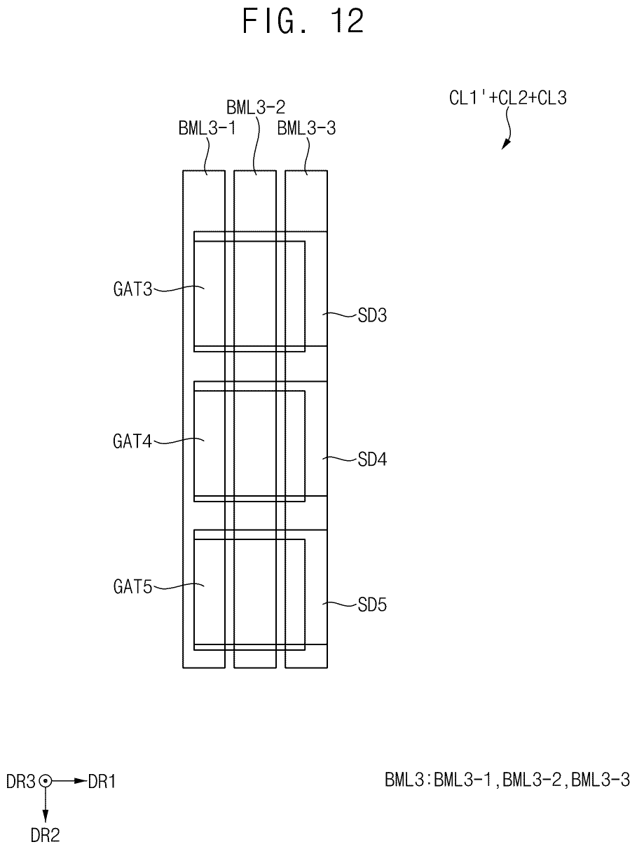

FIG. 11 is a plan view illustrating another example of a pixel included in the display device of FIG. 1. FIG. 12 is a plan view illustrating a third-first lower line BML3-1, a third-second lower line BML3-2, a third-third lower line BML3-3, a second double pattern GAT3, a third double pattern GAT4, a fourth double pattern GAT5, a first upper electrode SD3, a second upper electrode SD4, and a third upper electrode SD5 included in the display device DD of FIG. 1.

Components of the display device described with reference to FIGS. 11 and 12 are substantially a same as the configurations of the display device described with reference to FIGS. 3, 4, 5, 6, 7, and 8, except for the first conductive layer CL1′.

Hereinafter, contents that overlap contents described with reference to FIGS. 3, 4, 5, 6, 7, and 8 will be omitted or simplified.

Referring to FIGS. 11 and 12, the display device DD of FIG. 1 may include the first conductive layer CL1′. The first conductive layer CL1′ may include a third lower line BML3. The third lower line BML3 may include the third-first lower line BML3-1, the third-second lower line BML3-2, and the third-third lower line BML3-3.

The third-first lower line BML3-1, the third-second lower line BML3-2, and the third-third lower line BML3-3 may be spaced apart from each other. For example, The third-first lower line BML3-1 may be spaced apart from the third-second lower line BML3-2 in the first direction DR1. The third-second lower line BML3-2 may be spaced apart from the third-third lower line BML3-3 in the first direction DR1. In addition, each of the third-first lower line BML3-1, the third-second lower line BML3-2, and the third-third lower line BML3-3 may extend in the second direction DR2. In this specification, the third-first lower line BML3-1, the third-second lower line BML3-2, and the third-third lower line BML3-3 may be referred to as a first partial power voltage line, a second partial power voltage line, and a third partial power voltage line, respectively.

The first upper electrode SD3 may overlap a portion of each of the third-first lower line BML3-1, the third-second lower line BML3-2, and the third-third lower line BML3-3 in a plan view. The second upper electrode SD4 may overlap a portion of each of the third-first lower line BML3-1, the third-second lower line BML3-2, and the third-third lower line BML3-3 in a plan view. The third upper electrode SD5 may overlap a portion of each of the third-first lower line BML3-1, the third-second lower line BML3-2, and the third-third lower line BML3-3 in a plan view.

The second double pattern GAT3 may overlap a portion of each of the third-first lower line BML3-1 the third-second lower line BML3-2, and the third-third lower line BML3-3 in a plan view. The third double pattern GAT4 may overlap a portion of each of the third-first lower line BML3-1, the third-second lower line BML3-2, and the third-third lower line BML3-3 in a plan view. The fourth double pattern GAT5 may overlap a portion of each of the third-first lower line BML3-1, the third-second lower line BML3-2, and the third-third lower line BML3-3 in a plan view.

Referring further to FIG. 8, a contact hole may be defined in the buffer layer BFL, the gate insulating layer GIL, and the interlayer insulating layer ILD that penetrates the buffer layer BFL, the gate insulating layer GIL, and the interlayer insulating layer ILD in the thickness direction DR3. The first upper electrode SD3 may contact all of the third-first lower line BML3-1, the third-second lower line BML3-2, and the third-third lower line BML3-3 through the contact hole. The second and third upper electrodes SD4, and SD5 may also contact all of the third-first lower line BML3-1, the third-second lower line BML3-2, and the third-third lower line BML3-3 through the contact hole. That is, the first, second, and third upper electrodes SD3, SD4, and SD5 may electrically connect the third-first, third-second, and third-third lower lines BML3-1, BML3-2, and BML3-3 to each other.

A contact hole penetrating the interlayer insulating layer ILD in the thickness direction DR3 may also be defined in the interlayer insulating layer ILD. The first upper electrode SD3 may contact the second double pattern GAT3 through the contact hole. The second and third upper electrodes SD4, and SD5 may contact the third and fourth double patterns GAT4, and GAT5 respectively, through the contact hole.

The third-first lower line BML3-1, the third-second lower line BML3-2, and the third-third lower line BML3-3 may be connected in parallel to each other through the second, third, and fourth double patterns GAT3, GAT4, and GAT5 and the first, second, and third upper electrodes SD3, SD4, and SD5. In an embodiment, an area of each of the third-first lower line BML3-1, the third-second lower line BML3-2, and the third-third lower line BML3-3 may be about 0.22 cm² or less. Accordingly, an electrical resistance of the entire lines to which the first power voltage is applied may be further reduced by a parallel connection of the third-first lower line BML3-1, the third-second lower line BML3-2, and the third-third lower line BML3-3.

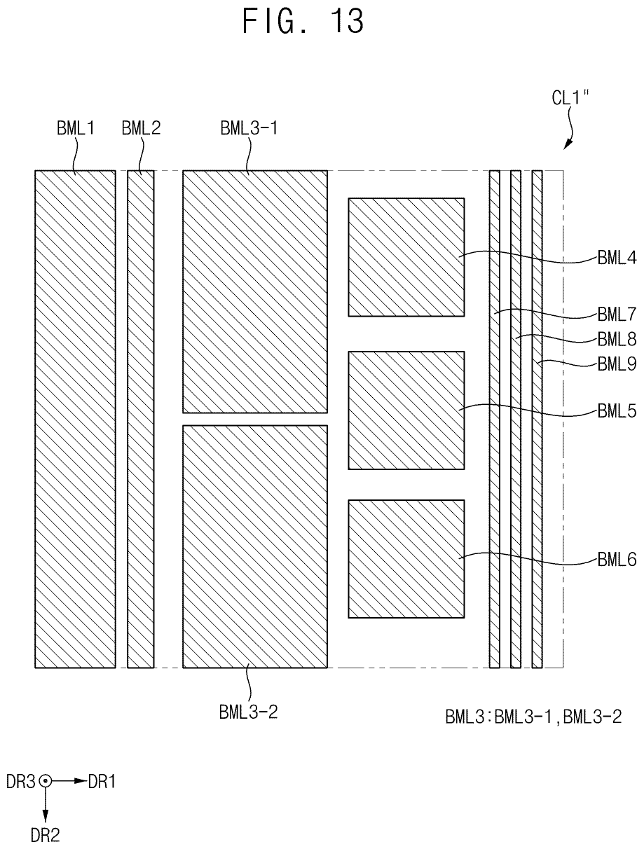

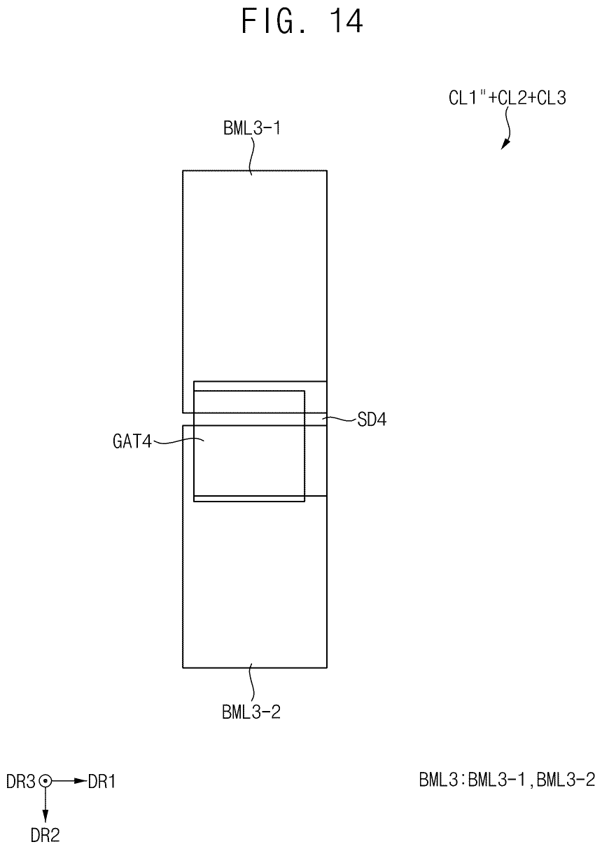

FIG. 13 is a plan view illustrating still another example of a pixel included in the display device of FIG. 1. FIG. 14 is a plan view illustrating a third-first lower line BML3-1, a third-second lower line BML3-2, a third double pattern GAT4, and a second upper electrode SD4 included in the display device DD of FIG. 1.

Components of the display device described with reference to FIGS. 13 and 14 are substantially a same as the configurations of the display device described with reference to FIGS. 3, 4, 5, 6, 7, and 8, except for the first conductive layer CL1″.

Hereinafter, contents that overlap contents described with reference to FIGS. 3, 4, 5, 6, 7, and 8 will be omitted or simplified.

Referring to FIGS. 13 and 14, the display device DD of FIG. 1 may include the first conductive layer CL1″. The first conductive layer CL1″may include the third lower line BML3. The third lower line BML3 may include the third-first lower line BML3-1 and the third-second lower line BML3-2 spaced apart from each other in the second direction DR2.

The second upper electrode SD4 may overlap a portion of each of the third-first lower line BML3-1 and the third-second lower line BML3-2 in a plan view. The third double pattern GAT4 may overlap a portion of each of the third-first lower line BML3-1 and the third-second lower line BML3-2 in a plan view.

Referring further to FIG. 8, a contact hole may be defined in the buffer layer BFL, the gate insulating layer GIL, and the interlayer insulating layer ILD that penetrates the buffer layer BFL, the gate insulating layer GIL, and the interlayer insulating layer ILD in the thickness direction DR3. The second upper electrode SD4 may contact both the third-first lower line BML3-1 and the third-second lower line BML3-2 through the contact hole. That is, the second upper electrode SD4 may electrically connect the third-first and third-second lower lines BML3-1 and BML3-2 to each other.

A contact hole penetrating the interlayer insulating layer ILD in the thickness direction DR3 may also be defined in the interlayer insulating layer ILD. The second upper electrode SD4 may contact the third double pattern GAT4 through the contact hole.

The third-first lower line BML3-1 and the third-second lower line BML3-2 may be connected to each other in parallel through the third double pattern GAT4 and the second upper electrode SD4. In an embodiment, an area of each of the third-first lower line BML3-1 and the third-second lower line BML3-2 may be about 0.22 cm² or less. Accordingly, an electrical resistance of the entire line to which the first power voltage is applied may be further reduced by a parallel connection of the third-first lower line BML3-1 and the third-second lower line BML3-2.

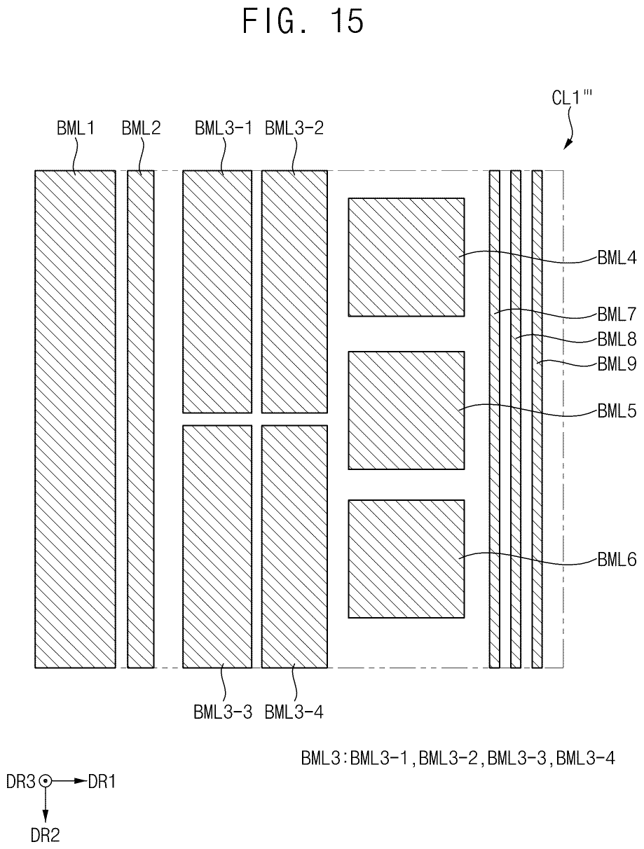

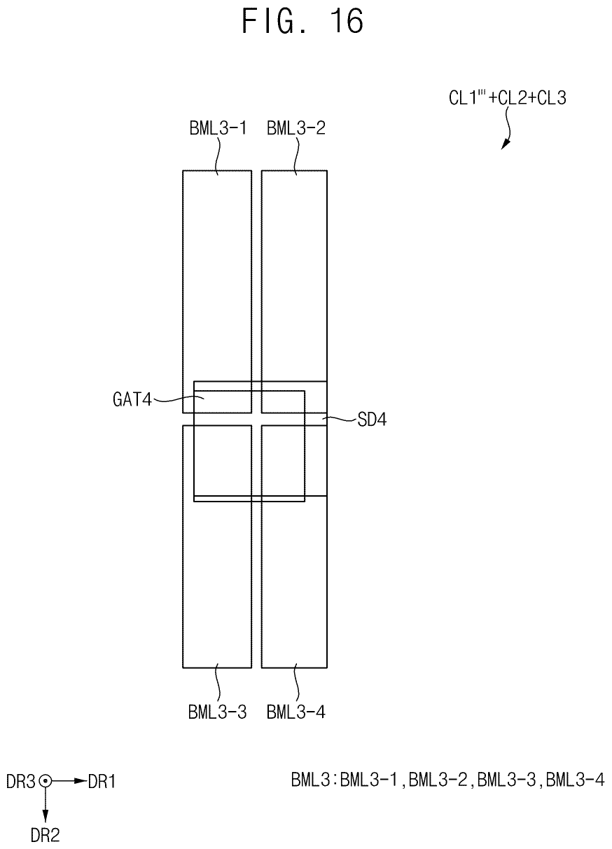

FIG. 15 is a plan view illustrating still another example of a pixel included in the display device DD of FIG. 1. FIG. 16 is a plan view illustrating a third-first lower line BML3-1, a third-second lower line BML3-2, a third-third lower line BML3-3, a third-fourth lower line BML3-4, a third double pattern GAT4, and a second upper electrode SD4 included in the display device DD of FIG. 1.

Components of the display device described with reference to FIGS. 15 and 16 are substantially a same as the configurations of the display device described with reference to FIGS. 3, 4, 5, 6, 7, and 8, except for the first conductive layer CL1″.

Hereinafter, contents that overlap contents described with reference to FIGS. 3, 4, 5, 6, 7, and 8 will be omitted or simplified.

Referring to FIGS. 15 and 16, the display device DD of FIG. 1 may include the first conductive layer CL1′″. The first conductive layer CL1′″ may include a third lower line BML3. The third lower line BML3 may include the third-first lower line BML3-1, the third-second lower line BML3-2, the third-third lower line BML3-3, and the third-fourth lower line BML3-4.

The third-first, third-second, third-third, and third-fourth lower lines BML3-1, BML3-2, BML3-3, and BML3-4 may be spaced apart from each other. For example, the third-first lower line BML3-1 may be spaced apart from the third-second lower line BML3-2 in the first direction DR1. The third-third lower line BML3-3 may be spaced apart from the third-fourth lower line BML3-4 in the first direction DR1. In addition, the third-first lower line BML3-1 may be spaced apart from the third-third lower line BML3-3 in the second direction DR2. The third-second lower line BML3-2 may be spaced apart from the third-fourth lower line BML3-4 in the second direction DR2. In this specification, the third-first, third-second, third-third, and third-fourth lower lines BML3-1, BML3-2, BML3-3, and BML3-4 may be referred to as the first, second, third, and fourth partial power voltage lines, respectively.

The second upper electrode SD4 may overlap each of the third-first, third-second, third-third, and third-fourth lower lines BML3-1, BML3-2, BML3-3, and BML3-4 and the third double pattern GAT4. The third double pattern GAT4 may overlap a portion of each of the third-first, third-second, third-third, and third-fourth lower lines BML3-1, BML3-2, BML3-3, and BML3-4 in a plan view. The second upper electrode SD4 may overlap a portion of each of the third-first, third-second, third-third, and third-fourth lower lines BML3-1, BML3-2, BML3-3, and BML3-4 in a plan view.

Referring further to FIG. 8, a contact hole may be defined in the buffer layer BFL, the gate insulating layer GIL, and the interlayer insulating layer ILD that penetrates the buffer layer BFL, the gate insulating layer GIL, and the interlayer insulating layer ILD in the thickness direction DR3. The second upper electrode SD4 may contact all of the third-first lower line BML3-1, the third-second lower line BML3-2, the third-third lower line BML3-3, and the third-fourth lower line BML3-4 through the contact hole. That is, the second upper electrode SD4 may electrically connect the third-first, third-second, third-third, and third-fourth lower lines BML3-1, BML3-2, BML3-3, and BML3-4 to each other.

A contact hole may also be defined in the interlayer insulating layer ILD that penetrates the interlayer insulating layer ILD in the thickness direction DR3. The second upper electrode SD4 may be in contact with the third double pattern GAT4 through the contact hole.

The third-first, third-second, third-third, and third-fourth lower lines BML3-1, BML3-2, BML3-3, and BML3-4 may be connected in parallel to each other through the third double pattern GAT4 and the second upper electrode SD4. In an embodiment, an area of each of the third-first, third-second, third-third, and third-fourth lower lines BML3-1, BML3-2, BML3-3, and BML3-4 may be about 0.22 cm² or less. Accordingly, an electric resistance of the entire lines to which the first power voltage is applied may be further reduced by a parallel connection of the third-first, third-second, third-third, and third-fourth lower lines BML3-1, BML3-2, BML3-3, and BML3-4.

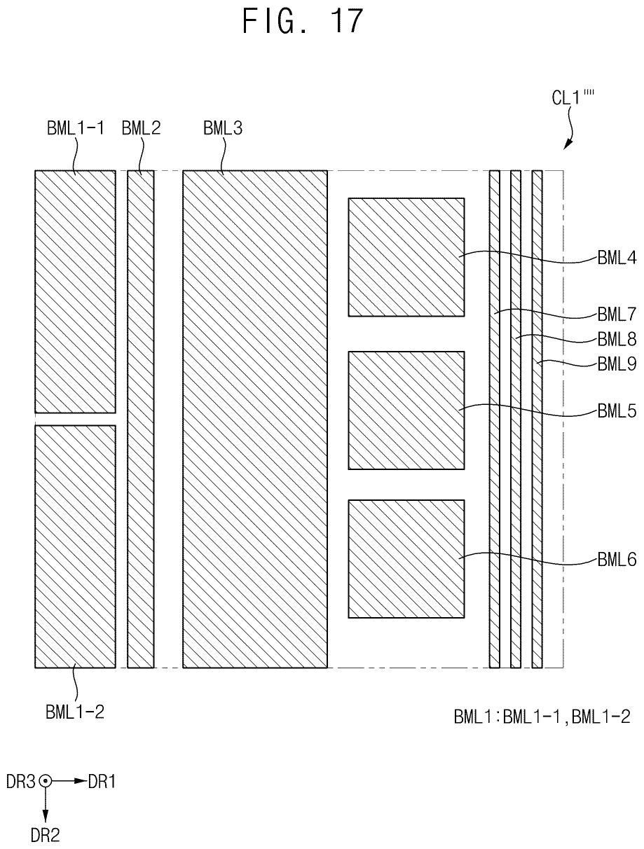

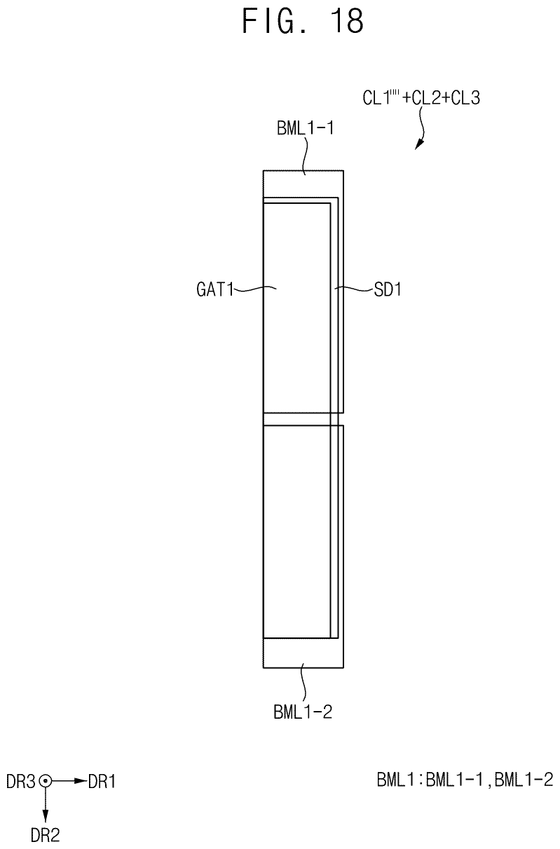

FIG. 17 is a plan view illustrating still another example of a pixel included in the display device DD of FIG. 1. FIG. 18 is a plan view illustrating a first-first lower line BML1-1, a first-second lower line BML1-2, a first double pattern GAT1, and a first line contact electrode SD1 included in the display device DD of FIG. 1.

Components of the display device described with reference to FIGS. 17 and 18 are substantially a same as the configurations of the display device described with reference to FIGS. 3, 4, 5, 6, 7, and 8, except for the first conductive layer CL1″″.

Hereinafter, contents that overlap contents described with reference to FIGS. 3, 4, 5, 6, 7, and 8 will be omitted or simplified.

Referring to FIGS. 17 and 18, the display device DD of FIG. 1 may include the first conductive layer CL1″″. The first conductive layer CL1″″ may include a first lower line BML1. As described above, the second power voltage may be applied to the first lower line BML1.

The first lower line BML1 may include the first-first lower line BML1-1 and the first-second lower line BML1-2. The first-first lower line BML1-1 and the first-second lower line BML1-2 may be spaced apart from each other. For example, the first-first lower line BML1-1 and the first-second lower line BML1-2 may be spaced apart in the second direction DR2. However, the direction in which the first-first lower line BML1-1 and the first-second lower line BML1-2 are spaced apart according to embodiments of the present disclosure may not be limited to the second direction DR2, and a direction in which the first-first lower line BML1-1 and the first-second lower line BML1-2 are spaced apart may be the first direction DR1.

The first line contact electrode SD1 may overlap a portion of each of the first-first lower line BML1-1 and the first-second lower line BML1-2 in a plan view. The first double pattern GAT1 may overlap a portion of each of the first-first lower line BML1-1 and the first-second lower line BML1-2 in a plan view.

Referring further to FIG. 8, a contact hole may be defined in the buffer layer BFL, the gate insulating layer GIL, and the interlayer insulating layer ILD that penetrates the buffer layer BFL, the gate insulating layer GIL, and the interlayer insulating layer ILD in the thickness direction DR3. The first line contact electrode SD1 may contact both the first-first lower line BML1-1 and the first-second lower line BML1-2 through the contact hole. That is, the first line contact electrode SD1 may electrically connect the first-first lower line BML1-1 and the first-second lower line BML1-2 to each other.

A contact hole penetrating the interlayer insulating layer ILD in the thickness direction DR3 may also be defined in the interlayer insulating layer ILD. The second upper electrode SD4 may contact the first double pattern GAT1 through the contact hole. In this specification, when the first lower line BML1 is divided into two or more, the first line contact electrode SD1 and the first double pattern GAT1 may be referred to as a connection pattern.

The first-first lower line BML1-1 and the first-second lower line BML1-2 may be connected to each other in parallel through the first double pattern GAT1 and the first line contact electrode SD1. In an embodiment, an area of each of the first-first lower line BML1-1 and the first-second lower line BML1-2 may be about 0.22 cm² or less. Accordingly, an electrical resistance of the entire first-first lower line BML1-1 and the first-second lower line BML1-2 to which the second power voltage is applied may be further reduced by a parallel connection of the first-first lower line BML1-1 and the first-second lower line BML1-2.

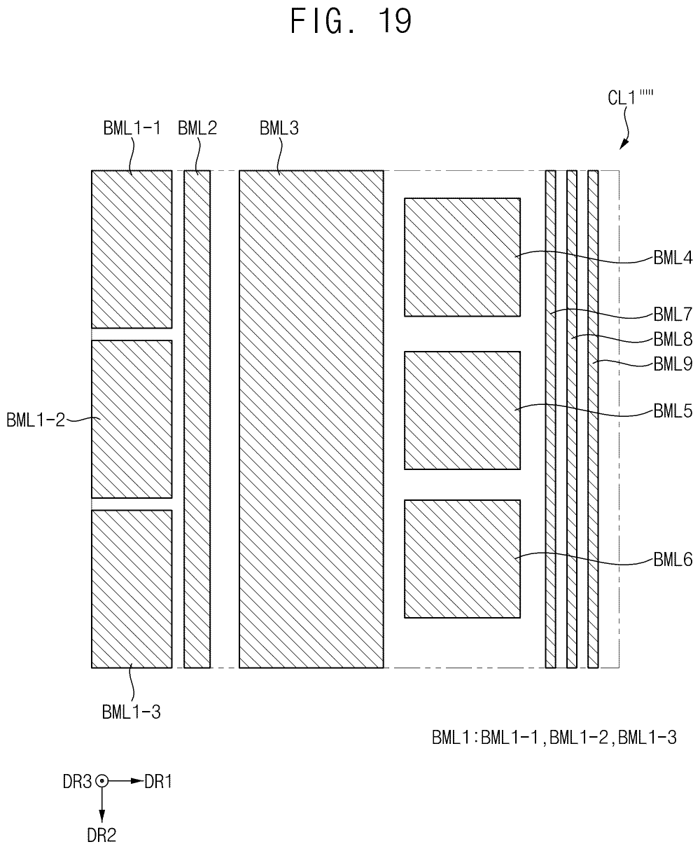

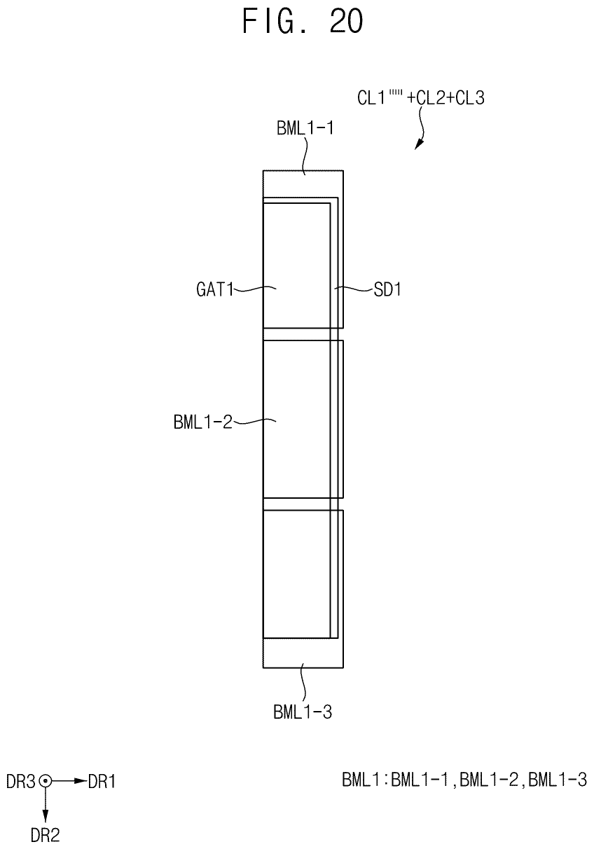

FIG. 19 is a plan view illustrating still another example of a pixel included in the display device DD of FIG. 1. FIG. 20 is a plan view illustrating a first-first lower line BML1-1, a first-second lower line BML1-2, a first-third lower line BML1-3, a first double pattern GAT1, and a first line contact electrode SD1 included in the display device of FIG. 1.

Components of the display device described with reference to FIGS. 19 and 20 are substantially a same as the configurations of the display device described with reference to FIGS. 3, 4, 5, 6, 7, and 8, except for the first conductive layer CL1′″″.

Hereinafter, contents that overlap contents described with reference to FIGS. 3, 4, 5, 6, 7, and 8 will be omitted or simplified.

Referring to FIGS. 19 and 20, the display device DD of FIG. 1 may include the first conductive layer CL1′″″. The first conductive layer CL1′″″ may include a first lower line BML1. The first lower line BML1 may include the first-first lower line BML1-1, the first-second lower line BML1-2, and the first-third lower line BML1-3.

The first-first lower line BML1-1, the first-second lower line BML1-2, and the first-third lower line BML1-3 may be spaced apart from each other. For example, the first-first lower line BML1-1 and the first-second lower line BML1-2 may be spaced apart in the second direction DR2. The first-second lower line BML1-2 and the first-third lower line BML1-3 may be spaced apart in the second direction DR2.

In the present disclosure, a direction in which the first-first lower line BML1-1, the first-second lower line BML1-2, and the first-third lower line BML1-3 are spaced apart may not be limited to the second direction DR2, and a direction in which the first-first lower line BML1-1, the first-second lower line BML1-2, and the first-third lower line BML1-3 are spaced apart may be the first direction DR1.

The first line contact electrode SD1 may overlap a portion of each of the first-first lower line BML1-1, the first-second lower line BML1-2, and the first-third lower line BML1-3 in a plan view. The first double pattern GAT1 may overlap with a portion of each of the first-first lower line BML1-1, the first-second lower line BML1-2, and the first-third lower line BML1-3 in a plan view.

Referring further to FIG. 8, a contact hole may be defined in the buffer layer BFL, the gate insulating layer GIL, and the interlayer insulating layer ILD that penetrates the buffer layer BFL, the gate insulating layer GIL, and the interlayer insulating layer ILD in the thickness direction DR3. The first line contact electrode SD1 may contact all of the first-first lower line BML1-1, the first-second lower line BML1-2, and the first-third lower line BML1-3 through the contact hole. That is, the first line contact electrode SD1 may electrically connect the first-first lower line BML1-1, the first-second lower line BML1-2, and the first-third lower line BML1-3 to each other.

A contact hole penetrating the interlayer insulating layer ILD in the thickness direction DR3 may also be defined in the interlayer insulating layer ILD. The first line contact electrode SD1 may contact the first double pattern GAT1 through the contact hole.

The first-first lower line BML1-1, the first-second lower line BML1-2, and the first-third lower line BML1-3 may be connected in parallel to each other through the first double pattern GAT1 and the first line contact electrode SD1. In an embodiment, an area of each of the first-first lower line BML1-1, the first-second lower line BML1-2, and the first-third lower line BML1-3 may be about 0.22 cm² or less. Accordingly, by a parallel connection of the first-first lower line BML1-1, the first-second lower line BML1-2, and the first-third lower line BML1-3, an electrical resistance of the entire first-first lower line BML1-1, the first-second lower line BML1-2, and the first-third lower line BML1-3 to which the second power voltage is applied may be further reduced.

The device according to the embodiments may be applied to a display device included in [an electric apparatus such as] a computer, a notebook, a mobile phone, a smartphone, a smart pad, a PMP, a PDA, an MP3 player, and the like.

Although the devices according to the embodiments have been described with reference to the drawings, the illustrated embodiments are examples, and may be modified and changed by a person having ordinary knowledge in the relevant technical field without departing from the technical spirit described in the following claims.

What is claimed is:

1. A display device comprising:
a substrate;
a first partial power voltage line disposed on the substrate, and to which a power voltage is configured to be applied;
a second partial power voltage line disposed in a same layer as the first partial power voltage line, spaced apart from the first partial power voltage line in a first direction, and to which the power voltage is configured to be applied; and
a first connection pattern disposed on the first partial power voltage line, and which electrically connects the first partial power voltage line and the second partial power voltage line.

2. The display device of claim 1, wherein each of the first partial power voltage line and the second partial power voltage line extends along a second direction which intersects with the first direction.

3. The display device of claim 1, wherein the first connection pattern overlaps a portion of each of the first partial power voltage line and the second partial power voltage line, in a plan view.

4. The display device of claim 1, further comprising:
a second connection pattern disposed on the first connection pattern, and electrically connected with the first connection pattern.

5. The display device of claim 4, wherein the second connection pattern overlaps a portion of each of the first partial power voltage line and the second partial power voltage line in a plan view.

6. The display device of claim 4, further comprising:
a gate insulating layer disposed between the first partial power voltage line and the second connection pattern; and
an interlayer insulating layer disposed between the first connection pattern and the second connection pattern.

7. The display device of claim 6, wherein a first contact hole which extends to the first partial power voltage line and a second contact hole which extends to the second partial power voltage line are defined in the gate insulating layer.

8. The display device of claim 7, wherein the first connection pattern contacts the first partial power voltage line through the first contact hole, and contacts the second partial power voltage line through the second contact hole.

9. The display device of claim 7, wherein in the interlayer insulating layer, a third contact hole extending to the second connection pattern is defined, and
the first connection pattern contacts the second connection pattern through the third contact hole.

10. The display device of claim 7, further comprising:
a third partial power voltage line spaced apart from the second partial power voltage line in the first direction, extending in a second direction which intersects with the first direction, and to which the power voltage is configured to be applied.

11. The display device of claim 10, wherein a third contact hole extending to the third partial power voltage line is defined in the gate insulating layer and the interlayer insulating layer, and
the first connection pattern contacts the third partial power voltage line through the third contact hole.

12. The display device of claim 10, wherein the first connection pattern and the second connection pattern contact a portion of each of the first partial power voltage line, the second partial power voltage line, and the third partial power voltage line, in a plan view.

13. The display device of claim 7, further comprising:
a third partial power voltage line spaced apart from the first partial power voltage line in a second direction which intersects the first direction, and to which the power voltage is configured to be applied; and
a fourth partial power voltage line spaced apart from the second partial power voltage line in the second direction, space apart from the third partial power voltage line in the first direction, and to which the power voltage is configured to be applied.

14. The display device of claim 13, wherein a third contact hole which extends to the third partial power voltage line and a fourth contact hole which extends to the fourth partial power voltage line are defined in the gate insulating layer and the interlayer insulating layer, and
the first connection pattern contacts the third partial power voltage line and fourth partial power voltage line through the third contact hole and the fourth contact hole, respectively.

15. The display device of claim 14, wherein the first connection pattern and the second connection pattern overlap a portion of each of the first partial power voltage line, the second partial power voltage line, third partial power voltage line, and fourth partial power voltage line, in a plan view.

16. A display device comprising:
a substate;
a first power voltage line disposed on the substrate, and to which a first power voltage is configured to applied;
a second power voltage line disposed in a same layer as the first partial power voltage line and including:
a first partial power voltage line spaced apart from the first power voltage line in a first direction, and to which a second power voltage, having a different level from the first power voltage, is configured to be applied; and
a second partial power voltage line spaced apart from the first partial power voltage line, and to which the second power voltage is configured to be applied; and
a connection pattern disposed on the first power voltage line, and electrically connecting the first partial power voltage line and the second partial power voltage line.

17. The display device of claim 16, wherein the first partial power voltage line and the second partial power voltage line are spaced apart from each other, and extend in a second direction which intersects with the first direction.

18. The display device of claim 16, wherein the first partial power voltage line and the second partial power voltage line are spaced apart in a second direction which intersects with the first direction.

19. The display device of claim 18, further comprising:
a third partial power voltage line spaced apart from the second partial power voltage line in the second direction, and to which the second power voltage is configured to be applied,
wherein the connection pattern electrically connects the first partial power voltage line, the second partial power voltage line, and the third partial power voltage line.

20. An electric apparatus comprising:
a display device comprising:
a substrate;
a first partial power voltage line disposed on the substrate, and to which a power voltage is configured to be applied;
a second partial power voltage line disposed in a same layer as the first partial power voltage line, spaced apart from the first partial power voltage line in a first direction, and to which the power voltage is configured to be applied; and
a first connection pattern disposed on the first partial power voltage line, and which electrically connects the first partial power voltage line and the second partial power voltage line.
